(19) United States
(12) Patent Application Publication
(10) Pub. No.: US 2025/0220302 A1
(43) Pub. Date: Jul. 3, 2025

(54) IMAGING APPARATUS, DISTANCE MEASURING APPARATUS, AND CONTROL METHOD FOR IMAGING APPARATUS

(71) Applicant: Nuvoton Technology Corporation Japan, Kyoto (JP)

(72) Inventors: Tohru YAMADA, Kyoto (JP); Takahiro MUROSHIMA, Kyoto (JP); Kazuaki SOGAWA, Kyoto (JP); Takeshi SOWA, Kyoto (JP)

(21) Appl. No.: 19/086,296

(22) Filed: Mar. 21, 2025

Related U.S. Application Data
(63) Continuation of application No. PCT/JP2023/034863, filed on Sep. 26, 2023.
(60) Provisional application No. 63/410,295, filed on Sep. 27, 2022.

(51) Int. Cl. H04N 23/667; H04N 25/76; H04N 25/771

(52) U.S. Cl. CPC H04N 23/667; H04N 25/771; H04N 25/7795

(57) ABSTRACT

An imaging apparatus includes: a first semiconductor layer; a unit cell that is provided in the first semiconductor layer and includes n pixels, where n is a natural number, and a charge accumulator in which charge generated in the n pixels accumulates; and a driving circuit. Each of the n pixels includes: a photoelectric converter; a first transfer transistor that includes a first control terminal; and a second transfer transistor that includes a second control terminal, and the driving circuit supplies a voltage corresponding to an operation mode selected from among a plurality of operation modes to the first semiconductor layer, the first control terminal, or the second control terminal.

### CROSS REFERENCE TO RELATED APPLICATIONS

This is a continuation application of PCT International Application No. PCT/JP2023/034863 filed on Sep. 26, 2023, designating the United States of America, which is based on and claims priority of U.S. Provisional Patent Application No. 63/410,295 filed on Sep. 27, 2022. The entire disclosures of the above-identified applications, including the specifications, drawings and claims are incorporated herein by reference in their entirety.

### FIELD

The present disclosure relates to an imaging apparatus, a distance measuring apparatus, and a control method for the imaging apparatus.

### BACKGROUND

Patent Literature (PTL) 1 discloses an imaging apparatus including a pixel array having a configuration in which pixels formed in a substrate are electrically insulated from one another by an insultation trench. Each pixel includes a photodiode and two transfer transistors. In the imaging apparatus disclosed in PTL 1, a positive voltage is applied to the substrate to turn off the transfer transistors at 0 V.

### CITATION LIST

### Patent Literature

PTL 1: Specification of U.S. patent application publication No. 2022/0272291

### SUMMARY

### Technical Problem

To achieve both image capturing and distance measurement in the imaging apparatus disclosed in PTL 1, it is required to make the electric potential of the photodiode deep in order to achieve high saturation during imaging and obtain a high-definition image. Meanwhile, high-speed readout of signal charge from the photodiode is necessary during the distance measurement. To read out signal charge at a high speed, it is necessary to set the control voltages of the transfer transistors high, which increases power consumption. As such, in the imaging apparatus disclosed in PTL 1, there is the issue of not being able to achieve obtainment of a high-definition image and distance measurement with low power consumption at the same time.

Thus, the present disclosure provides, for example, the imaging apparatus that can achieve both obtainment of a high-definition image and distance measurement with low power consumption.

### Solution to Problem

An imaging apparatus according to one aspect of the present disclosure includes: a first semiconductor layer; a unit cell that is provided in the first semiconductor layer and includes n pixels, where n is a natural number, and a charge accumulator in which charge generated in the n pixels accumulates; and a driving circuit, in which each of the n pixels includes: a photoelectric converter; a first transfer transistor that includes a first control terminal, a first input and output terminal connected to the photoelectric converter, and a second input and output terminal connected to the charge accumulator; and a second transfer transistor that includes a second control terminal, a third input and output terminal connected to the photoelectric converter, and a fourth input and output terminal different from the third input and output terminal, and the driving circuit supplies a voltage corresponding to an operation mode selected from among a plurality of operation modes to the first semiconductor layer, the first control terminal, or the second control terminal.

A distance measuring apparatus according to another aspect of the present disclosure includes: a light source; the imaging apparatus according to the above aspect; and an arithmetic circuit that calculates the distance to a target object in accordance with a signal output from the imaging apparatus.

A control method for the imaging apparatus according to still another aspect of the present disclosure includes: in an operation mode in which to expose at least one of the n pixels to blinking light with a second wavelength, in a period of exposure to the blinking light with the second wavelength, alternating between conduction and nonconduction to avoid simultaneous conduction of the first transfer transistor and the second transfer transistor; and in an operation mode in which to expose at least one of the n pixels to light with a first wavelength, in a period of exposure to the light with the first wavelength, maintaining the first transfer transistor and the second transfer transistor in a non-conducting state, and causing only the first transfer transistor to enter a conducting state at a predetermined timing.

Moreover, yet another aspect of the present disclosure can be achieved as a program for causing a computer to perform the above control method. Alternatively, yet another aspect of the present disclosure can be achieved as a non-transitory computer-readable recording medium having recorded thereon the program.

### Advantageous Effects

The present disclosure can provide, for example, an imaging apparatus that can achieve both obtainment of a high-definition image and distance measurement with low power consumption.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a configuration of an endoscopy system according to an embodiment.

FIG. 2 illustrates a configuration of an imaging apparatus according to the embodiment.

FIG. 3 illustrates a circuit configuration of a unit cell according to the embodiment.

FIG. 4 illustrates an example of control of operation modes in the imaging apparatus according to the embodiment.

FIG. 5 is a figure for explaining a distance measuring method based on a CW-ToF method.

FIG. 6 is a figure for explaining a distance measuring method based on a pulse ToF method.

FIG. 7A is a timing chart illustrating a first driving example of a distance measuring mode using the CW-TOF method.

FIG. 7B illustrates a relationship between irradiation light and reflected light and each frame period in the first driving example illustrated in FIG. 7A.

FIG. 8 is a timing chart illustrating a second driving example of the distance measuring mode using the CW-ToF method.

FIG. 9A is a timing chart illustrating a third driving example of the distance measuring mode using the CW-ToF method.

FIG. 9B is a timing chart illustrating a variation example of the third driving example of the distance measuring mode using the CW-ToF method.

FIG. 10A is a timing chart illustrating a driving example of a distance measuring mode using the pulse ToF method.

FIG. 10B illustrates a relationship between irradiation light and reflected light and each frame period in the example illustrated in FIG. 10A.

FIG. 10C illustrates examples of control signals supplied to two transfer transistors in the example illustrated in FIG. 10A.

FIG. 11 is a timing chart illustrating a first driving example of an RGB mode.

FIG. 12 is a timing chart illustrating a second driving example of the RGB mode.

FIG. 13A illustrates an electric potential within the unit cell in the RGB mode.

FIG. 13B illustrates an electric potential within the unit cell in the ToF mode.

FIG. 14 is a schematic plan view illustrating an example of a pixel according to the embodiment.

FIG. 15A is a schematic plan view illustrating another example of the pixel according to the embodiment.

FIG. 15B is a schematic plan view illustrating another example of the pixel according to the embodiment.

FIG. 15C is a schematic plan view illustrating another example of the pixel according to the embodiment.

FIG. 15D is a schematic plan view illustrating another example of the pixel according to the embodiment.

FIG. 15E is a schematic plan view illustrating another example of the pixel according to the embodiment.

FIG. 15F is a schematic plan view illustrating another example of the pixel according to the embodiment.

FIG. 16 illustrates a configuration of a driving circuit according to the embodiment.

FIG. 17 illustrates circuit configurations of a pixel control circuit and a substrate voltage supply circuit according to the embodiment.

FIG. 18A illustrates an example of an electric potential supplied to the control terminal of a transfer transistor in the RGB mode.

FIG. 18B illustrates an example of an electric potential supplied to the control terminal of the transfer transistor in the ToF mode.

FIG. 18C illustrates another example of the electric potential supplied to the control terminal of the transfer transistor in the ToF mode.

FIG. 19A illustrates examples of electric potentials supplied to the control terminals of the transfer transistor and a reset transistor in the RGB mode.

FIG. 19B illustrates examples of electric potentials supplied to the control terminals of transfer transistors and the reset transistor in the ToF mode.

FIG. 20A illustrates examples of electric potentials supplied to the control terminals of the transfer transistor and the reset transistor and the substrate in the RGB mode.

FIG. 20B illustrates examples of electric potentials supplied to the control terminals of the transfer transistors and the reset transistor and the substrate in the ToF mode.

FIG. 20C illustrates variation examples of the electric potentials supplied to the control terminals of the transfer transistors and the reset transistor and the substrate in the ToF mode.

FIG. 21 illustrates an electric potential within the unit cell when the voltage of a capacitor is controlled, in the ToF mode.

FIG. 22 is a plan view of a photoelectric converter according to the embodiment.

FIG. 23A is a cross-sectional view taken along line XXIII-XXIII in FIG. 22.

FIG. 23B is a cross-sectional view of a pixel according to a comparison example corresponding to line XXIII-XXIII in FIG. 22.

FIG. 24 is a cross-sectional view illustrating a cross-sectional configuration of the photoelectric converter when negative voltages are supplied to the control terminals of the transfer transistors.

FIG. 25 illustrates the dynamic range of the imaging apparatus with respect to the area ratio of a hole accumulation region.

### DESCRIPTION OF EMBODIMENTS

### Overview of the Present Disclosure

An imaging apparatus according to the first aspect of the present disclosure includes: a first semiconductor layer; a unit cell that is provided in the first semiconductor layer and includes n pixels, where n is a natural number, and a charge accumulator in which charge generated in the n pixels accumulates; and a driving circuit, in which each of the n pixels includes: a photoelectric converter; a first transfer transistor that includes a first control terminal, a first input and output terminal connected to the photoelectric converter, and a second input and output terminal connected to the charge accumulator; and a second transfer transistor that includes a second control terminal, a third input and output terminal connected to the photoelectric converter, and a fourth input and output terminal different from the third input and output terminal, and the driving circuit supplies a voltage corresponding to an operation mode selected from among a plurality of operation modes to the first semiconductor layer, the first control terminal, or the second control terminal.

As such, in the imaging apparatus according to the aspect, a suitable voltage based on the operation mode can be supplied to the first semiconductor layer, the first control terminal, or the second control terminal. Thus, even if the electric potential of the photoelectric converter is made deeper to obtain a high-definition image, it is possible to measure the distance with high accuracy while suppressing power consumption. This can achieve both obtainment of a high-definition image and distance measurement with low power consumption.

An imaging apparatus according to the second aspect of the present disclosure is the imaging apparatus according to the first aspect, in which the plurality of operation modes include: a first operation mode in which to expose at least one of the n pixels to light with a first wavelength; and a second operation mode in which to expose at least one of the n pixels to blinking light with a second wavelength.

This makes it possible to obtain a high-quality image in the first operation mode and measure the distance with low power consumption in the second operation mode.

An imaging apparatus according to the third aspect of the present disclosure is the imaging apparatus according to the first aspect or the second aspect, in which the driving circuit includes: a first voltage supply circuit that supplies a voltage to the first semiconductor layer; and a second voltage supply circuit that supplies a voltage to at least one of the first control terminal or the second control terminal.

Thus, it is possible to supply a suitable voltage to each of the first semiconductor layer and at least one of the first control terminal or the second control terminal. This can achieve both obtainment of a high-definition image and distance measurement with low power consumption.

An imaging apparatus according to the fourth aspect of the present disclosure is the imaging apparatus according to the second aspect, in which the driving circuit includes a first voltage supply circuit that supplies a voltage to the first semiconductor layer, and the first voltage supply circuit includes: a first signal line set to a first electric potential; a second signal line set to a second electric potential different from the first electric potential; and a first connection circuit that switches between the first signal line and the second signal line according to the operation mode and connects the first signal line or the second signal line to the first semiconductor layer.

Thus, by setting voltage levels (electric potentials) to the two signal lines beforehand, and changing the connection relationship between the first semiconductor layer and the two signal lines, it is possible to readily change the voltage level of a voltage supplied to the first semiconductor layer.

An imaging apparatus according to the fifth aspect of the present disclosure is the imaging apparatus according to the fourth aspect, in which the second electric potential is lower than the first electric potential, and when the first operation mode is selected, the first connection circuit connects the first signal line to the first semiconductor layer, and when the second operation mode is selected, the first connection circuit connects the second signal line to the first semiconductor layer.

As such, in the second operation mode, by decreasing the voltage level of a voltage supplied to the first semiconductor layer, even if the change width (amplitude) of the voltage of a transfer transistor is small, it is possible to efficiently read out signal charge from the photoelectric converter. Thus, it is possible to perform high-speed readout of signal charge with high accuracy and enhance the accuracy of distance measurement.

An imaging apparatus according to the sixth aspect of the present disclosure is the imaging apparatus according to one of the second aspect, the fourth aspect, or the fifth aspect, in which the driving circuit includes a second voltage supply circuit that supplies a voltage to at least one of the first control terminal or the second control terminal, and the second voltage supply circuit includes: one or more third signal lines set to at least one of a third electric potential or a fourth electric potential higher than the third electric potential; one or more fourth signal lines set to at least one of a fifth electric potential or a sixth electric potential higher than the fifth electric potential; and a second connection circuit that switches between the one or more third signal lines and the one or more fourth signal lines according to the operation mode, and connects the one or more third signal lines or the one or more fourth signal lines to at least one of the first control terminal or the second control terminal.

Thus, by setting voltage levels (electric potentials) to the signal lines beforehand, and changing the connection relationship between the first semiconductor layer and the signal lines and the connection relationship between the control terminals and the signal lines, it is possible to readily change the voltage levels of voltages supplied to the first semiconductor layer and the control terminals.

An imaging apparatus according to the seventh aspect of the present disclosure is the imaging apparatus according to the sixth aspect, in which an electric potential difference between the fourth electric potential and the third electric potential differs from an electric potential difference between the sixth electric potential and the fifth electric potential.

Thus, by setting voltage levels (electric potentials) to the signal lines beforehand, and changing the connection relationship between the first semiconductor layer and the signal lines and the connection relationship between the control terminals and the signal lines, it is possible to readily change the voltage levels of voltages supplied to the first semiconductor layer and the control terminals.

An imaging apparatus according to the eighth aspect of the present disclosure is the imaging apparatus according to the sixth aspect or the seventh aspect, in which an electric potential difference between the fourth electric potential and the third electric potential is larger than an electric potential difference between the sixth electric potential and the fifth electric potential, and when the first operation mode is selected, the second connection circuit connects the one or more third signal lines to at least one of the first control terminal or the second control terminal, and when the second operation mode is selected, the second connection circuit connects the one or more fourth signal lines to at least one of the first control terminal or the second control terminal.

As such, in the second operation mode, it is possible to make the change width (amplitude) of the voltage of the transfer transistor small, which can decrease the power consumption.

An imaging apparatus according to the ninth aspect of the present disclosure is the imaging apparatus according to the second aspect, the fourth aspect, or the fifth aspect, in which the driving circuit includes a second voltage supply circuit that supplies a voltage to at least one of the first control terminal or the second control terminal, and the second voltage supply circuit includes: a seventh signal line set to a seventh electric potential; an eighth signal line set to an eighth electric potential different from the seventh electric potential; and a third connection circuit that switches between the seventh signal line and the eighth signal line according to the operation mode, and connects the seventh signal line or the eighth signal line to at least one of the first control terminal or the second control terminal.

Thus, by setting voltage levels (electric potentials) to the two signal lines beforehand, and changing the connection relationship between at least one of the first control terminal or the second control terminal and the two signal lines, it is possible to readily change the voltage level of a voltage supplied to the at least one of the first control terminal or the second control terminal.

An imaging apparatus according to the tenth aspect of the present disclosure is the imaging apparatus according to the ninth aspect, in which the eighth electric potential is lower than the seventh electric potential, and when the first operation mode is selected, the third connection circuit connects the seventh signal line to at least one of the first control terminal or the second control terminal, and when the second operation mode is selected, the third connection circuit connects the eighth signal line to at least one of the first control terminal or the second control terminal.

As such, in the second operation mode, by setting the voltage level of a voltage supplied to at least one of the first control terminal or the second control terminal to a low voltage level, even if the change width (amplitude) of the voltage of the transfer transistor is small, it is possible to efficiently read out signal charge from the photoelectric converter. Thus, it is possible to perform high-speed readout of signal charge with high accuracy and enhance the accuracy of distance measurement.

An imaging apparatus according to the eleventh aspect of the present disclosure is the imaging apparatus according to one of the second aspect and the fourth to tenth aspects, in which the unit cell includes: a capacitor that includes a first electrode and a second electrode; and a switching device connected in series between the first electrode and the charge accumulator, and the switching device maintains conduction between the capacitor and the charge accumulator in the second operation mode, and interrupts conduction between the capacitor and the charge accumulator in the first operation mode.

As such, in the second operation mode, a part of charge accumulated in the photoelectric converter can also be accumulated in the capacitor, which can achieve high saturation.

An imaging apparatus according to the twelfth aspect of the present disclosure is the imaging apparatus according to the eleventh aspect, in which the second operation mode, the driving circuit causes an electric potential to be supplied to the second electrode to be lower than an electric potential supplied to the fourth input and output terminal.

As such, since it is possible to make the electric potentials of the charge accumulator and the capacitor low, it is possible to read out signal charge from the photoelectric converter at a high speed and with high accuracy. Thus, it is possible to further enhance the accuracy of distance measurement.

A distance measuring apparatus according to the thirteenth aspect of the present disclosure includes: a light source; the imaging apparatus according to one of the first to eighth aspects; and an arithmetic circuit that calculates the distance to a target object in accordance with a signal output from the imaging apparatus.

Thus, as with the imaging apparatus described above, it is possible to achieve both obtainment of a high-definition image and distance measurement with low power consumption.

A control method for the imaging apparatus according to the fourteenth aspect of the present disclosure includes: in an operation mode in which to expose at least one of the n pixels to blinking light with a second wavelength, in a period of exposure to the blinking light with the second wavelength, alternating between conduction and nonconduction to avoid simultaneous conduction of the first transfer transistor and the second transfer transistor; and in an operation mode in which to expose at least one of the n pixels to light with a first wavelength, in a period of exposure to the light with the first wavelength, maintaining the first transfer transistor and the second transfer transistor in a non-conducting state, and causing only the first transfer transistor to enter a conducting state at a predetermined timing.

Thus, as with the imaging apparatus described above, it is possible to achieve both obtainment of a high-definition image and distance measurement with low power consumption.

It should be noted that the unit cell stated in the above aspects is formed in the first semiconductor layer, and the first semiconductor layer is, for example, the substrate, a well, or an epitaxial layer.

Embodiments are specifically described below with reference to the drawings.

It should be noted that the embodiments described below each indicate a comprehensive or specific example. The numerical values, shapes, materials, constituent elements, arrangement and connection of the constituent elements, steps, order of steps, and other details indicated in the embodiments described below are merely examples, and do not intend to limit the present disclosure. Moreover, the constituent elements not recited in the independent claims, among those described in the embodiments below are described as optional constituent elements.

Moreover, the figures are schematic illustrations and are not necessarily precise depictions. Accordingly, for instance, the scales used in the figures need not necessarily be the same. Moreover, in the figures, substantially the same elements are assigned the same reference symbols, and overlapping explanations are omitted or simplified.

Moreover, in the specification, terms indicating relationships between elements such as parallel or vertical, terms describing the shapes of elements such as rectangular, and a numerical value range are not expressions indicating only the strict meanings but expressions intended to include substantially equivalent ranges such as a difference of around several percentages.

Moreover, in the specification, the terms, above and below do not indicate the upward direction (vertically upward) or the downward direction (vertically downward) in absolute spatial recognition, and are used as terms defined by the relative positional relationship based on the staking order in a layered configuration. Moreover, the terms, above and below are used not only in the case where a constituent element is present between two constituent elements spaced apart from each other, but also in the case where two constituent elements are so disposed that the two constituent elements are tightly in contact with each other.

Moreover, in the specification, a thickness direction means a thickness direction of a substrate and a direction perpendicular to the main surface of the substrate. Moreover, the expression, in a plan view means, unless otherwise noted, that a thing is viewed in the direction perpendicular to the main surface of the substrate.

Moreover, in the specification, a wavelength band of at least 380 nm and at most 780 nm is considered the visible light band. A wavelength band of at least 780 nm and at most 2500 nm is considered the near-infrared band.

Moreover, in the specification, the input and output terminal of a transistor means a terminal where at least one of input or output of current (charge) or a voltage is performed. When the transistor is a field-effect transistor (FET) such as a metal-oxide-semiconductor field-effect transistor (MOSFET) or a thin-film transistor (TFT), the source and drain thereof are input and output terminals. When the transistor is a bipolar transistor, the emitter and collector thereof are input and output terminals. It should be noted that the gate of the FET and the base of the bipolar transistor are control terminals.

Moreover, in the specification, unless otherwise noted, ordinal numerals such as the first and the second do not indicate the number or order of constituent elements, but are used to avoid the mix-up of constituent elements of the same kind and distinguish one from another.

### Embodiment

### [Endoscopy System]

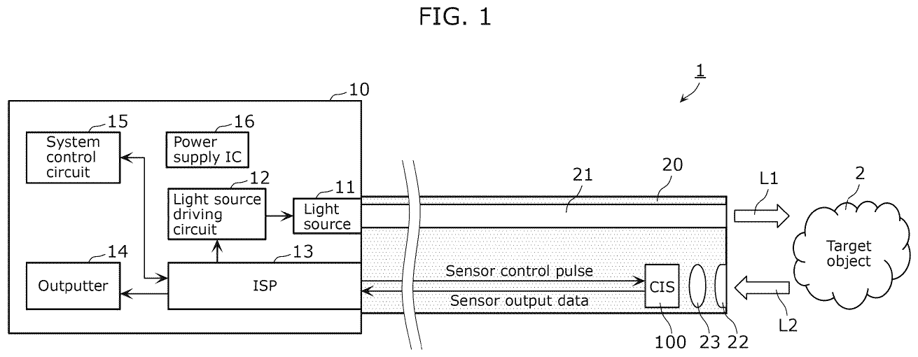

First, an endoscopy system according to an embodiment is described with reference to FIG. 1. FIG. 1 illustrates a configuration of endoscopy system 1 according to the embodiment.

Endoscopy system 1 is an example of a distance measuring apparatus including an imaging apparatus. As illustrated in FIG. 1, endoscopy system 1 can measure the distance to target object 2 by irradiating target object 2 with light L1 and receiving reflected light L2 that has reflected off target object 2 after the irradiation of light L1. Moreover, endoscopy system 1 can obtain a visible light image of target object 2. Endoscopy system 1 according to the embodiment has operation modes. The operation modes include an imaging mode for generating a visible light image and a distance measuring mode for generating a range image.

As illustrated in FIG. 1, endoscopy system 1 includes main body 10 and insertion section 20. In using endoscopy system 1, insertion section 20 is inserted into the body of, for example, a person or an animal. That is, target object 2 is part of the body.

Main body 10 is the section of endoscopy system 1 that is not to be inserted into the body. As illustrated in FIG. 1, main body 10 includes light source 11, light source driving circuit 12, image signal processor (ISP) 13, outputter 14, system control circuit 15, and power supply integrated circuit (IC) 16.

Light source 11 emits light for irradiating target object 2. Specifically, light source 11 can emit light with a first wavelength for the imaging mode and blinking light with a second wavelength for the distance measuring mode. The first wavelength is, for example, included in a visible light band. The light with the first wavelength is, for example, white light. The second wavelength is a wavelength different from the first wavelength. For instance, the second wavelength is included in a near-infrared band. The blinking light is light that periodically changes between bright and dark. The cycle of the blinking light is, for example, at least 1 MHZ and at most 200 MHZ, and 50 MHz as a non-limiting example.

Light source 11 includes, for example, a light emitting diode (LED), a semiconductor laser device, or an organic electroluminescence (EL) device. As an example, light source 11 includes a blue LED or a blue laser device that emits blue light and a yellow phosphor that emits yellow light due to excitation by blue light. As light with the first wavelength, light source 11 emits white light that is the mixed light of the blue light and the yellow light. Moreover, light source 11 includes a near-infrared laser device that emits near-infrared light as blinking light with the second wavelength.

Light source driving circuit 12 is a circuit for driving light source 11. Specifically, light source driving circuit 12 controls the timings to turn on and off light source 11. For instance, light source driving circuit 12 generates power to turn on light source 11 from power supplied from power supply IC 16, and supplies the generated power to light source 11. Light source driving circuit 12 can control the timings to turn on and off light source 11 by adjusting the timings to start and stop supplying power to light source 11.

Light source driving circuit 12 is configured by including at least one of various electronic components, such as an IC, a resistor, a transistor, a diode, a capacitor, an inductor, and a transformer. Light source driving circuit 12 may be integrated with another constituent element such as power supply IC 16 or system control circuit 15.

ISP 13 is an example of an arithmetic circuit, and processes a signal output from imaging apparatus 100, that is, sensor output data. In the imaging mode, ISP 13 generates a visible light image by using the sensor output data. In the distance measuring mode, ISP 13 calculates the distance to target object 2 by using the sensor output data. ISP 13 generates a range image indicating the distance to target object 2 for each pixel. Each of a visible light image and a range image is a still image or a moving image (video).

Outputter 14 outputs the visible light image and the range image generated by ISP 13. For instance, outputter 14 is a communication interface (IF) for communicating wired or wirelessly with an external device such as a display. For instance, outputter 14 is an output terminal to which a communication cable is connectable. Alternatively, outputter 14 may include an antenna and a wireless processing circuit.

System control circuit 15 performs the overall control of endoscopy system 1. Specifically, system control circuit 15 performs, for example, selection of an operation mode of endoscopy system 1 (switching between operation modes) and outputting of a control signal to each constituent element of endoscopy system 1 according to the selected operation mode.

System control circuit 15 is achieved as, for example, a large-scale integration (LSI), which is an integrated circuit. It should be noted that the integrated circuit is not limited to an LSI and may be a dedicated circuit or a general-purpose processor. For instance, system control circuit 15 may be a microcontroller. The microcontroller includes, for example, nonvolatile memory storing a program, volatile memory as a temporary memory area for executing the program, an input-output port, and a processor that executes the program. Moreover, system control circuit 15 may be a field programmable gate array (FPGA) that can be programmed or a reconfigurable processor in which the connections and settings of circuit cells within an LSI are reconfigurable. Functions performed by system control circuit 15 may be achieved as software or hardware.

Power supply IC 16 is a power supply circuit that processes power supplied from an external power supply such as a commercial power supply or a power storage apparatus. For instance, power supply IC 16 includes, for example, an AC/DC converter and/or a DC/DC converter.

Although not illustrated in FIG. 1, endoscopy system 1 may include an operation means that accepts operation input from a user. The operation means may be a physical operation button or switch and may be a touch panel, for example. The operation means may be a communication interface (IF) that accepts operation input via a remote operation terminal such as a remote controller.

Insertion section 20 is a flexible portion and, at least the tip end portion (the end portion on the opposite side from main body 10) of insertion section 20 is inserted into the body during the use of endoscopy system 1. As a non-limiting example, the length of insertion section 20 is within the range from 3 m to 5 m. As illustrated in FIG. 1, insertion section 20 includes light guide member 21, object lens 22, condenser lens 23, and imaging apparatus 100.

Light guide member 21 guides light emitted by light source 11 to the tip end portion and emits the light from the tip end portion toward target object 2 as light L1. As a non-limiting example, light guide member 21 is an optical fiber.

Object lens 22 and condenser lens 23 are optical systems for causing imaging apparatus 100 to receive reflected light L2 from target object 2. As long as the lenses enable imaging apparatus 100 to receive reflected light L2, the types and number of lenses are not limited to particular types or a particular number. Moreover, an optical device other than the lenses may be provided.

Imaging apparatus 100 outputs an image signal obtained by photoelectrically converting reflected light L2 from target object 2. Specifically, in the imaging mode, imaging apparatus 100 photoelectrically converts the light ray (reflected light L2) that has reflected off target object 2 among light rays with the first wavelength emitted by light source 11. In the distance measuring mode, imaging apparatus 100 photoelectrically converts the light ray (reflected light L2) that has reflected off target object 2 among blinking light rays with the second wavelength emitted by light source 11.

Imaging apparatus 100 is connected to ISP 13 and one or more cables (not illustrated). Imaging apparatus 100 operates according to the sensor control pulse transmitted from ISP 13 via the cables. Examples of the sensor control pulse include master clock MCLK and vertical synchronizing signal VD. Moreover, imaging apparatus 100 outputs an image signal to ISP 13 as the sensor output data. In the embodiment, imaging apparatus 100 is a complementary metal-oxide-semiconductor (CMOS) image sensor (CIS). Imaging apparatus 100 is, for example, a backside illumination CIS.

### [Imaging Apparatus]

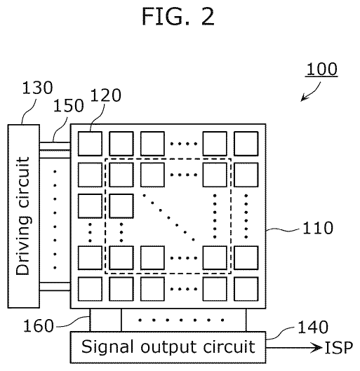

Next, a specific configuration of imaging apparatus 100 is described with reference to FIG. 2. FIG. 2 illustrates a configuration of imaging apparatus 100 according to the embodiment.

As illustrated in FIG. 2, imaging apparatus 100 includes sensor array 110, driving circuit 130, and signal outputting circuit 140. Moreover, imaging apparatus 100 includes a plurality of control lines 150, a plurality of power supply lines (not illustrated), and a plurality of vertical signal lines 160.

Sensor array 110 includes a plurality of unit cells 120 two-dimensionally arranged in a matrix. As a non-limiting example, at least several hundred unit cells 120 or at least several thousand unit cells 120 are provided in each of a row direction and a column direction. The plurality of unit cells 120 are provided in a first semiconductor layer. The first semiconductor layer is, for example, a substrate. The substrate is, for example, a semiconductor substrate containing, as a main ingredient, a semiconductor such as silicon. The first semiconductor layer may be a well region or an epitaxial layer.

Each of the plurality of unit cells 120 includes n pixels. Here, n is a natural number. Each of the n pixels includes a photoelectric converter. Specific configurations of a pixel and unit cell 120 are described later.

It should be noted that in FIG. 2, the area surrounded by the dashed line within sensor array 110 is an effective pixel area. An effective pixel is a pixel for recording and outputting of a video signal and distance measuring calculation. The pixels other than effective pixels are also referred to as, for example, dummy pixels and are disposed around the effective pixel area in FIG. 2. It should be noted that the dummy pixels need not be provided and the pixels of all unit cells 120 included in sensor array 110 may be effective pixels.

Driving circuit 130 is a circuit that controls each of the plurality of unit cells 120. Driving circuit 130 and each unit cell 120 are electrically connected via the plurality of control lines 150. Driving circuit 130 drives each control line 150 according to the operation mode selected from among the operation modes. Specifically, by outputting a control signal to each control line 150, driving circuit 130 controls, for example, the exposure timing and signal outputting timing of each pixel included in each unit cell 120. Moreover, driving circuit 130 may change the value (electric potential, voltage level) of a power supply voltage to be supplied to each of the plurality of power supply lines. A specific configuration and an operation example of driving circuit 130 are described later.

Signal outputting circuit 140 is connected to the plurality of unit cells 120 via the plurality of vertical signal lines 160. Signal outputting circuit 140 outputs, as image signals, signals read out from the plurality of unit cells 120 or the pixels via the plurality of vertical signal lines 160 to ISP 13.

### [Unit Cell]

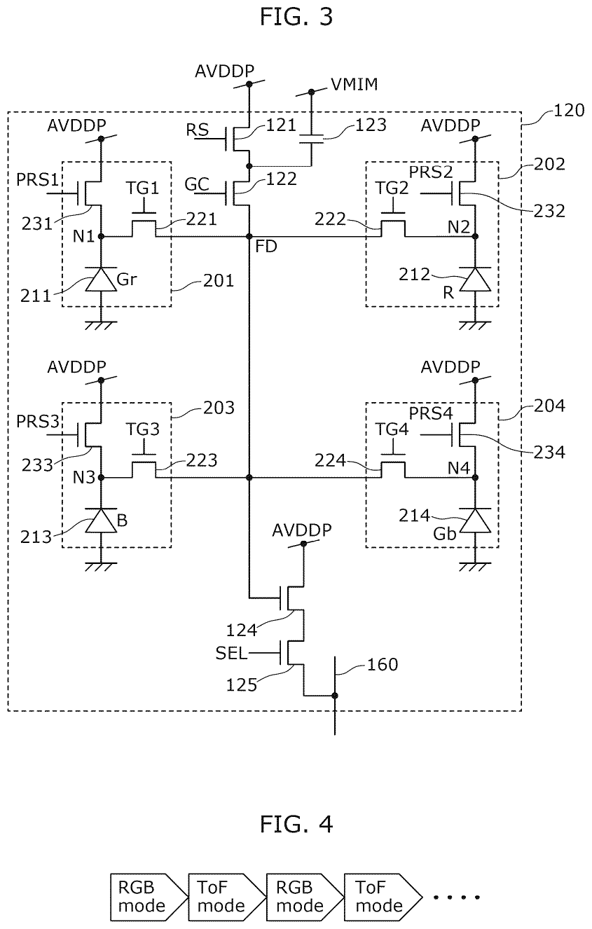

Then, a specific circuit configuration of unit cell 120 is described with reference to FIG. 3. FIG. 3 illustrates a circuit configuration of unit cell 120 according to the embodiment.

It should be noted that since the plurality of unit cells 120 provided in sensor array 110 have the same configuration, the following descriptions focus on one of the plurality of unit cells 120 as a typical example. Moreover, in the embodiment, a case where a number n indicating the number of pixels included in unit cell 120 is four is described as an instance.

As illustrated in FIG. 3, unit cell 120 includes the four pixels, pixels 201, 202, 203, and 204 and charge accumulator FD for accumulating charge generated in the four pixels, pixels 201, 202, 203, and 204. Furthermore, unit cell 120 includes reset transistor 121, capacitor connection transistor 122, capacitor 123, readout transistor 124, and selection transistor 125.

Moreover, control lines TG1, TG2, TG3, and TG4, control lines PRS1, PRS2, PRS3, and PRS4, and control lines RS, GC, and SEL are connected to unit cell 120 as the plurality of control lines 150. Control lines TG1, TG2, TG3, and TG4, control lines PRS1, PRS2, PRS3, and PRS4, and control lines RS, GC, and SEL are connected to the same constituent elements in each of a plurality of unit cells 120 arranged in the row direction. For instance, control line TG1 is an example of a first control line and is connected to the gate of first transfer transistor 221 in pixel 201 of each of the plurality of unit cells 120 arranged in the row direction. Control line PRS1 is an example of a second control line and is connected to the gate of second transfer transistor 231 in pixel 201 of each of the plurality of unit cells 120 arranged in the row direction. Moreover, for instance, control line RS is connected to the gate of reset transistor 121 in each of the plurality of unit cells 120 arranged in the row direction.

Moreover, as the plurality of power supply lines, power supply lines AVDDP and VMIM and power supply line GND (not illustrated) set to the ground electric potential are provided in unit cell 120. It should be noted that the ground electric potential is an example of a reference electric potential and, for example, 0 V. Each of power supply lines AVDDP, VMIM, and GND is connected to the same constituent element in each of a plurality of unit cells 120 arranged in at least one of the row direction or the column direction. For instance, power supply line VMIM is connected to one (the second electrode) of the electrodes of capacitor 123 in each of the plurality of unit cells 120 arranged in a matrix. Moreover, at least one of the plurality of power supply lines may be a power supply line for supplying a voltage (substrate voltage) to a substrate in which the plurality of unit cells 120 (the pixels) are provided.

The four pixels, pixels 201, 202, 203, and 204 correspond to red pixel (R), green pixels (Gr, Gb), and blue pixel (B) necessary to generate an RGB image (color image), which is an example of a visible light image. Specifically, pixels 201 and 204 are green pixels (Gr, Gb), pixel 202 is red pixel (R), and pixel 203 is blue pixel (B). RGB pixels are arranged in a Bayer array. It should be noted that the array of RGB is not limited to a particular array.

Moreover, each of the four pixels, pixels 201, 202, 203, and 204 has sensitivity not only for the visible light band but also for the second wavelength (near-infrared band). This enables each of the four pixels, pixels 201, 202, 203, and 204 to receive blinking light with the second wavelength, which makes it possible to generate a range image.

Pixel 201 includes photoelectric converter 211 and first transfer transistor 221 and second transfer transistor 231 that are connected to photoelectric converter 211. It should be noted that pixel 201 may include a filter (not illustrated) that transmits a green light ray (light with the first wavelength) and a near-infrared light ray (light with the second wavelength) among incident light rays and suppresses the transmission of the rays other than the above-mentioned rays.

Photoelectric converter 211 photoelectrically converts incident light and generates an amount of charge corresponding to the light intensity. Photoelectric converter 211 is, for example, a photodiode provided in the substrate. Photoelectric converter 211 has sensitivity for each of green light and near-infrared light.

The anode of photoelectric converter 211 (a photodiode) is connected to the ground electric potential. The cathode of photoelectric converter 211 is connected to each of first transfer transistor 221 and second transfer transistor 231. It should be noted that the connection point of first transfer transistor 221, second transfer transistor 231, and photoelectric converter 211 is illustrated as node N1.

First transfer transistor 221 is a field-effect transistor (FET) including a gate, a source, and a drain. The gate of first transfer transistor 221 is an example of a first control terminal and is connected to control line TG1. One of the source or drain of first transfer transistor 221 is an example of a first input and output terminal, and is connected to photoelectric converter 211. The other of the source or drain of first transfer transistor 221 is an example of a second input and output terminal different from the first input and output terminal, and is connected to charge accumulator FD.

Second transfer transistor 231 is a FET including a gate, a source, and a drain. The gate of second transfer transistor 231 is an example of a second control terminal, and is connected to control line PRS1. One of the source or drain of second transfer transistor 231 is an example of a third input and output terminal, and is connected to photoelectric converter 211. The other of the source or drain of second transfer transistor 231 is an example of a fourth input and output terminal different from the third input and output terminal, and is connected to power supply line AVDDP.

Pixel 202 includes photoelectric converter 212 and first transfer transistor 222 and second transfer transistor 232 that are connected to photoelectric converter 212. It should be noted that pixel 202 may include a filter (not illustrated) that transmits a red light ray (light with the first wavelength) and a near-infrared light ray (light with the second wavelength) among incident light rays and suppresses the transmission of the rays other than the above-mentioned rays.

Photoelectric converter 212 photoelectrically converts incident light and generates an amount of charge corresponding to the light intensity. Photoelectric converter 212 is, for example, a photodiode provided in the substrate. Photoelectric converter 212 has sensitivity for each of red light and near-infrared light.

The anode of photoelectric converter 212 (a photodiode) is connected to the ground electric potential. The cathode of photoelectric converter 212 is connected to each of first transfer transistor 222 and second transfer transistor 232. It should be noted that the connection point of first transfer transistor 222, second transfer transistor 232, and photoelectric converter 212 is illustrated as node N2.

First transfer transistor 222 is a FET including a gate, a source, and a drain. The gate of first transfer transistor 222 is an example of the first control terminal and is connected to control line TG2. One of the source or drain of first transfer transistor 222 is an example of the first input and output terminal, and is connected to photoelectric converter 212. The other of the source or drain of first transfer transistor 222 is an example of the second input and output terminal different from the first input and output terminal, and is connected to charge accumulator FD.

Second transfer transistor 232 is a FET including a gate, a source, and a drain. The gate of second transfer transistor 232 is an example of the second control terminal, and is connected to control line PRS2. One of the source or drain of second transfer transistor 232 is an example of the third input and output terminal, and is connected to photoelectric converter 212. The other of the source or drain of second transfer transistor 232 is an example of the fourth input and output terminal different from the third input and output terminal, and is connected to power supply line AVDDP.

Pixel 203 includes photoelectric converter 213 and first transfer transistor 223 and second transfer transistor 233 that are connected to photoelectric converter 213. It should be noted that pixel 203 may include a filter (not illustrated) that transmits a blue light ray (light with the first wavelength) and a near-infrared light ray (light with the second wavelength) among incident light rays and suppresses the transmission of the rays other than the above-mentioned rays.

Photoelectric converter 213 photoelectrically converts incident light and generates an amount of charge corresponding to the light intensity. Photoelectric converter 213 is, for example, a photodiode provided in the substrate. Photoelectric converter 213 has sensitivity for each of blue light and near-infrared light.

The anode of photoelectric converter 213 (a photodiode) is connected to the ground electric potential. The cathode of photoelectric converter 213 is connected to each of first transfer transistor 223 and second transfer transistor 233. It should be noted that the connection point of first transfer transistor 223, second transfer transistor 233, and photoelectric converter 213 is illustrated as node N3.

First transfer transistor 223 is a FET including a gate, a source, and a drain. The gate of first transfer transistor 223 is an example of the first control terminal and is connected to control line TG3. One of the source or drain of first transfer transistor 223 is an example of the first input and output terminal, and is connected to photoelectric converter 213. The other of the source or drain of first transfer transistor 223 is an example of the second input and output terminal different from the first input and output terminal, and is connected to charge accumulator FD.

Second transfer transistor 233 is a FET including a gate, a source, and a drain. The gate of second transfer transistor 233 is an example of the second control terminal, and is connected to control line PRS3. One of the source or drain of second transfer transistor 233 is an example of the third input and output terminal, and is connected to photoelectric converter 213. The other of the source or drain of second transfer transistor 233 is an example of the fourth input and output terminal different from the third input and output terminal, and is connected to power supply line AVDDP.

Pixel 204 may include photoelectric converter 214 and first transfer transistor 224 and second transfer transistor 234 that are connected to photoelectric converter 214. It should be noted that pixel 204 includes a filter (not illustrated) that transmits a green light ray (light with the first wavelength) and a near-infrared light ray (light with the second wavelength) among incident light rays and suppresses the transmission of the rays other than the above-mentioned rays.

Photoelectric converter 214 photoelectrically converts incident light and generates an amount of charge corresponding to the light intensity. Photoelectric converter 214 is, for example, a photodiode provided in the substrate. Photoelectric converter 214 has sensitivity for each of green light and near-infrared light.

The anode of photoelectric converter 214 (a photodiode) is connected to the ground electric potential. The cathode of photoelectric converter 214 is connected to each of first transfer transistor 224 and second transfer transistor 234. It should be noted that the connection point of first transfer transistor 224, second transfer transistor 234, and photoelectric converter 214 is illustrated as node N4.

First transfer transistor 224 is a FET including a gate, a source, and a drain. The gate of first transfer transistor 224 is an example of the first control terminal and is connected to control line TG4. One of the source or drain of first transfer transistor 224 is an example of the first input and output terminal, and is connected to photoelectric converter 214. The other of the source or drain of first transfer transistor 224 is an example of the second input and output terminal different from the first input and output terminal, and is connected to charge accumulator FD.

Second transfer transistor 234 is a FET including a gate, a source, and a drain. The gate of second transfer transistor 234 is an example of the second control terminal, and is connected to control line PRS4. One of the source or drain of second transfer transistor 234 is an example of the third input and output terminal, and is connected to photoelectric converter 214. The other of the source or drain of second transfer transistor 234 is an example of the fourth input and output terminal different from the third input and output terminal, and is connected to power supply line AVDDP.

Charge accumulator FD is shared by the four pixels, pixels 201, 202, 203, and 204. Specifically, charge accumulator FD can accumulate charge generated in each of photoelectric converters 211, 212, 213, and 214 in the respective pixels. Charge accumulator FD is, for example, an impurity region provided in the semiconductor substrate and a plug and wiring connected to the impurity region.

Reset transistor 121 is provided to reset the electric potential of charge accumulator FD. Reset transistor 121 is an example of a switching device, and is connected in series between power supply line AVDDP and charge accumulator FD. In the embodiment, reset transistor 121 is connected to charge accumulator FD via capacitor connection transistor 122. Reset transistor 121 is a FET including a gate, a source, and a drain. The gate of reset transistor 121 is connected to control line RS. One of the source or drain of reset transistor 121 is connected to power supply line AVDDP. The other of the source or drain of reset transistor 121 is connected to charge accumulator FD via capacitor connection transistor 122. When reset transistor 121 is brought into conduction (in the embodiment, capacitor connection transistor 122 is also brought into conduction), charge accumulator FD will be connected to power supply line AVDDP, thereby resetting the electric potential of charge accumulator FD.

Capacitor connection transistor 122 is provided to switch the connection between capacitor 123 and charge accumulator FD. Capacitor connection transistor 122 is an example of a switching device, and is connected in series between capacitor 123 and charge accumulator FD. Capacitor connection transistor 122 is a FET including a gate, a source, and a drain. The gate of capacitor connection transistor 122 is connected to control line GC. One of the source or drain of capacitor connection transistor 122 is connected to one (the first electrode) of the electrodes of capacitor 123. The other of the source or drain of capacitor connection transistor 122 is connected to charge accumulator FD. It should be noted that capacitor connection transistor 122 may be used to reset the electric potential of charge accumulator FD.

Capacitor 123 is provided to increase the amount of charge that unit cell 120 can accumulate, and expand the dynamic range. Capacitor 123 includes the first electrode and the second electrode. The first electrode of capacitor 123 is connected to charge accumulator FD via capacitor connection transistor 122. The second electrode of capacitor 123 is connected to power supply line VMIM. When capacitor connection transistor 122 is brought into conduction, a portion of the charge that has flowed into charge accumulator FD from each pixel can be accumulated in capacitor 123. Capacitor 123 is, for example, a capacitor having a metal-insulator-metal (MIM) structure provided above the semiconductor substrate. However, a specific configuration of capacitor 123 is not limited to a particular configuration. For instance, parasitic capacitance due to, for example, wiring and an electrode may be used as capacitor 123.

Readout transistor 124 is provided to read out the charge accumulated in charge accumulator FD, specifically to output a signal corresponding to the amount of charge to vertical signal line 160. Readout transistor 124 is a FET including a gate, a source, and a drain. The gate of readout transistor 124 is connected to charge accumulator FD. One of the source or drain of readout transistor 124 is connected to power supply line AVDDP. The other of the source or drain of readout transistor 124 is connected to vertical signal line 160 via selection transistor 125.

Selection transistor 125 is provided to control the timing at which readout transistor 124 reads out the charge accumulated in charge accumulator FD. Selection transistor 125 is a FET including a gate, a source, and a drain. The gate of selection transistor 125 is connected to control line SEL. One of the source or drain of selection transistor 125 is connected to readout transistor 124. The other of the source or drain of selection transistor 125 is connected to vertical signal line 160. When selection transistor 125 is brought into conduction, readout transistor 124 reads out the charge.

Each of the transistors included in unit cell 120 includes, as a source and a drain, impurity regions provided in the semiconductor substrate, and includes, as a gate, an electrode provided above the semiconductor substrate with a gate insulator film interposed therebetween. The two transistors connected in series may share an impurity region. For instance, the other of the source or drain of reset transistor 121 and the one of the source or drain of capacitor connection transistor 122 may share one impurity region.

It should be noted that the configuration of unit cell 120 described above is a mere example and can be changed as appropriate. For instance, a number n indicating the number of pixels included in unit cell 120 may be one, two, or at least five. Moreover, for instance, selection transistor 125 may be connected between readout transistor 124 and power supply line AVDDP. Moreover, for instance, capacitor connection transistor 122 and capacitor 123 need not be provided. Moreover, for instance, the transistors included in unit cell 120 are n-channel transistors. However, the transistors may be p-channel transistors. Alternatively, the transistors may be bipolar transistors.

### [Operation]

Then, operations of endoscopy system 1 according to the embodiment are described.

As described above, endoscopy system 1 has the operation modes including the imaging mode and the distance measuring mode. Imaging apparatus 100 included in endoscopy system 1 performs a different operation according to the operation mode.

The imaging mode is an example of the first operation mode of imaging apparatus 100, and is an operation mode in which to expose at least one of the n pixels included in unit cell 120, that is, pixels 201 to 204 to light with the first wavelength. In the embodiment, since the imaging mode is an RGB mode for generating an RGB image (a color image), all of the four pixels, pixels 201 to 204 included in unit cell 120 are exposed to light. In the RGB mode, light source 11 emits white light as light with the first wavelength, and causes the pixels of imaging apparatus 100 to receive the reflected light. It should be noted that the RGB image is an image in which each pixel of the image corresponds to unit cell 120 of imaging apparatus 100 and includes the respective RGB values (luminance values).

The distance measuring mode is an example of the second operation mode of imaging apparatus 100, and is an operation mode in which to expose at least one of the n pixels included in unit cell 120, that is, pixels 201 to 204 to blinking light with the second wavelength. In the embodiment, the distance measuring mode is a time of flight (ToF) mode using the ToF method. In the ToF mode, the distance to target object 2 is calculated from the time it takes for light emitted from light source 11 to travel to target object 2 and return to each pixel (time-of-flight of light), and a range image is generated. Specifically, in the ToF mode, light source 11 emits blinking light with the near-infrared band as blinking light with the second wavelength, and causes at least one of the pixels of imaging apparatus 100 to receive the reflected light. It should be noted that the range image is an image in which each pixel indicates the distance to target object 2.

FIG. 4 illustrates an example of switching between the operation modes in imaging apparatus 100 according to the embodiment. As illustrated in FIG. 4, the RGB mode and the ToF mode are continuously performed with the modes being alternately switched. Thus, it is possible to obtain an RGB image and a range image by one-time measurement (by inserting insertion section 20 into the body one time). It is possible to check the interior of the body by visual observation on the basis of the RGB image, while at the same time avoiding bringing insertion section 20 into contact with the interior of the body on the basis of the range image. It should be noted that switching between the RGB mode and the ToF mode may be manually performed in accordance with, for example, the operation input by a user.

Although details are described later, in a control method for imaging apparatus 100 according to the embodiment, in the ToF mode, in the period of exposure to blinking light with the second wavelength (reflected light L2), conduction and nonconduction are alternated to avoid simultaneous conduction of the first transfer transistor and the second transfer transistor. Moreover, in the RGB mode, in the period of exposure to light with the first wavelength (reflected light L2), the first transfer transistor and the second transfer transistor are maintained in a non-conducting state, and only the first transfer transistor is brought into a conducting state at a predetermined timing (within the pulse period). This can achieve both highly accurate distance measurement and obtainment of a high-definition RGB image.

### [Tof Mode]

Then, a specific example of the ToF mode is described.

The ToF mode is performed by irradiating target object 2 with blinking light, receiving the reflected light (the blinking light) that has reflected off target object 2, and processing an electrical signal obtained through photoelectric conversion. In the ToF mode, a continuous-wave (CW)-ToF method using a continuous wave (light) or a pulse ToF method using pulse light is used.

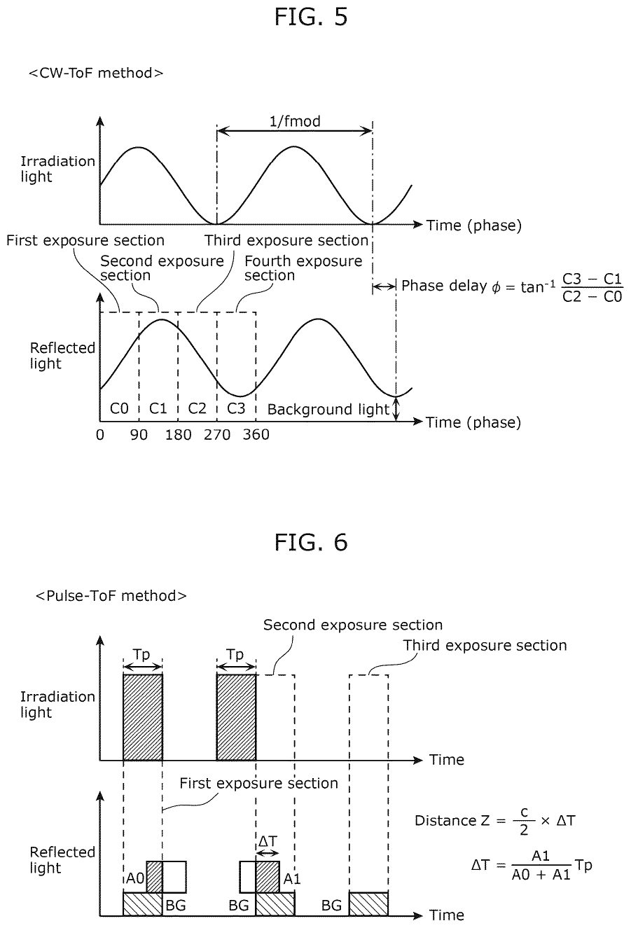

FIG. 5 is a figure for explaining a distance measuring method based on the CW-ToF method. As illustrated in FIG. 5, the intensity of irradiation light with which target object 2 is irradiated continuously changes in a predetermined cycle. The irradiation light is a continuous wave with a constat period and amplitude. An intensity change cycle is expressed as 1/fmod, using modulation frequency fmod.

Phase delay φ occurs in the reflected light when compared with the irradiation light, depending on the distance to target object 2. In the CW-ToF method, light is received in each of four exposure sections into which the period of the irradiation light was divided, and phase delay φ is calculated from Expression (1), using intensities C0, C1, C2, and C3 in the respective exposure sections.

$$[ Math . 1 ]$$

$$ϕ = {tan}^{- 1} \frac{C 3 - C 1}{C 2 - C 0} \qquad Expression ( 1 )$$

When the light velocity is defined as c, distance Z to target object 2 is expressed by Expression (2), using phase delay φ.

$$[ Math . 2 ]$$

$$Z = \frac{c}{2} \times \frac{ϕ}{2 π f mod} \qquad Expression ( 2 )$$

It should be noted that although the reflected light contains a background light component (a noise component), a difference between the intensities is calculated in each of the denominator and numerator of the right-hand side of Expression (1), thereby canceling out the background light component.

In the CW-TOF method, the accuracy of distance measurement can be enhanced by making modulation frequency fmod high. Meanwhile, a distance measurable range (distance measurement range) is decreased as modulation frequency fmod becomes higher. This is because maximum value Zₘₐₓ of measurable distance Z is reached when φ=2n (=360 degrees) in Expression (2), and is expressed as c/(2fmod). With regard to a reduction in the distance measurement range, the distance measurement range can be increased by measuring the distance using different modulation frequencies and combining the results of distance measurement.

FIG. 6 is a figure for explaining a distance measuring method based on the pulse ToF method. As illustrated in FIG. 6, target object 2 is repeatedly irradiated with pulse light with pulse width (period) Tp as irradiation light at predetermined time intervals.

A delay of a certain amount of time ΔT from the pulse light occurs in the reflected light, depending on the distance to target object 2. In the pulse ToF method, the reflected light is received in at least two exposure sections set to periods different from the irradiation periods of the pulse light. In the instance illustrated in FIG. 6, the same section as the section of the pulse light is set as the first exposure section, the section that starts simultaneously with the stop of irradiation of the pulse light is set as the second exposure section, and the section in which there is no possibility of receiving the reflected light is set as the third exposure section. The third exposure section is provided to detect background light component BG. When background light component BG is sufficiently small in quantity, the third exposure section need not be set.

Distance Z to target object 2 is expressed by Expression (3) below on the basis of delay time ΔT.

$$[ Math . 3 ]$$

$$Z = \frac{c}{2} \times Δ T = \frac{c}{2} \times \frac{A 1}{A 0 + A 1} \times Tp \qquad Expression ( 3 )$$

A0 is the intensity of the reflected light received in the first exposure section, and A1 is the intensity of the reflected light received in the second exposure section. Specifically, A0 is obtained by subtracting the signal intensity (background light component BG) obtained in the third exposure section from the signal intensity obtained in the first exposure section. A1 is obtained by subtracting the signal intensity (background light component BG) obtained in the third exposure section from the signal intensity obtained in the second exposure section.

In the pulse ToF method, the accuracy of distance measurement can be enhanced with a decrease in pulse width Tp. Meanwhile, the distance measurable range (distance measurement range) is decreased with a decrease in pulse width Tp. This is because maximum value Zₘₐₓ of measurable distance Z is reached when A0=0 in Expression (3), and is expressed as (c×Tp)/2. With regard to a reduction in the distance measurement range, the distance measurement range can be increased by measuring the distance with multiple times of exposure and combining the results of distance measurement.

### [CW-ToF Method]

Hereinafter, a specific operation of imaging apparatus 100 in a distance measuring mode using the CW-ToF method is described.

It should be noted that in the embodiment, each of reset transistor 121, capacitor connection transistor 122, selection transistor 125, first transfer transistors 221, 222, 223, and 224, and second transfer transistors 231, 232, 233, and 234 included in unit cell 120 becomes conductive (is turned on) when a voltage level (electric potential) supplied to the gate thereof is a high level (High), and becomes nonconductive (is turned off) when the voltage level (electric potential) supplied to the gate thereof is a low level (Low).

### <First Driving Example>

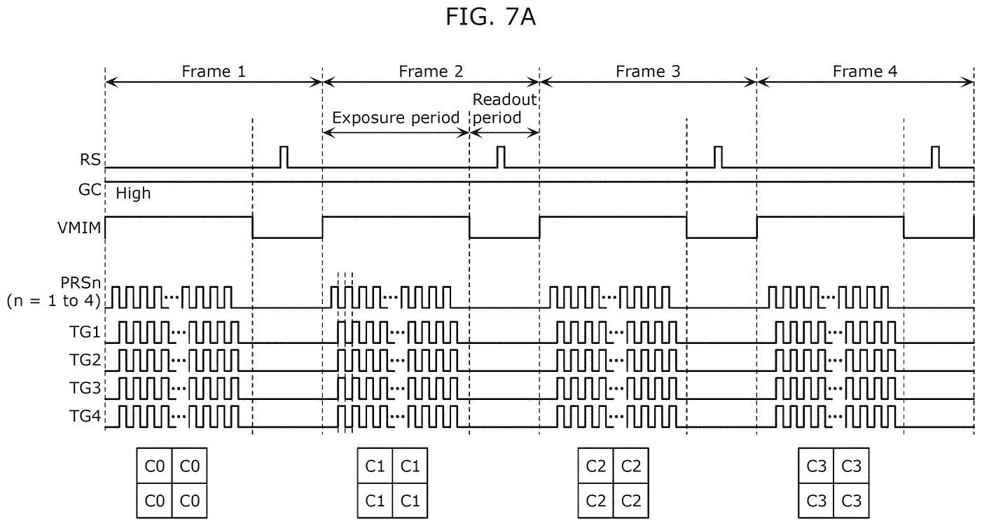

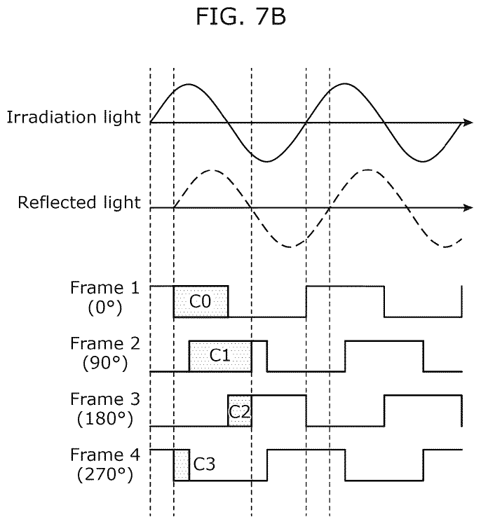

First, a first driving example of imaging apparatus 100 in the CW-ToF method is described with reference to FIGS. 7A and 7B. In the first driving example, all of the four pixels, pixels 201 to 204 included in unit cell 120 are used for distance measurement.

FIG. 7A is a timing chart illustrating a first driving example of a distance measuring mode using the CW-ToF method. FIG. 7B illustrates a relationship between irradiation light and reflected light and each frame period in the first driving example illustrated in FIG. 7A.

In FIG. 7A, RS indicates the temporal change of the voltage level (electric potential) of control line RS connected to the gate of reset transistor 121. GC indicates the temporal change of the voltage level (electric potential) of control line GC connected to the gate of capacitor connection transistor 122. VMIM indicates the temporal change of the voltage level (electric potential) of power supply line VMIM connected to the second electrode of capacitor 123.

PRSn, where n=1 to 4, indicates the temporal changes of the voltage levels (electric potentials) of control lines PRS1, PRS2, PRS3, and PRS4 connected to the gates of second transfer transistors 231, 232, 233, and 234. TG1, TG2, TG3, and TG4 indicate the temporal changes of the voltage levels (electric potentials) of control lines TG1, TG2, TG3, and TG4 connected to the gates of first transfer transistors 221, 222, 223, and 224. It should be noted that in the specification, TG1 to TG4 may be stated as TGn, where n=1 to 4.

Frames 1 to 4 are frame periods having the same length. Each frame period corresponds to the unit period of processing by imaging apparatus 100 (endoscopy system 1). Each of frames 1 to 4 includes an exposure period and a readout period.

The exposure period is a period during which the pixels included in unit cell 120 are caused to receive reflected light. The readout period is a period during which charge accumulated in charge accumulator FD (and capacitor 123) is read out to vertical signal line 160. Since the readout processing is the same as the readout processing performed by a typical CMOS image sensor, the explanations thereof are omitted. It should be noted that when control line RS is changed to a high level in the readout period, the electric potential of charge accumulator FD is reset. This can suppress signals from being mixed among the frames and thus enhance the accuracy of distance measurement.

The four squares arranged in two rows and two columns illustrated at the bottom of FIG. 7A correspond to the four pixels, pixels 201, 202, 203, and 204 included in unit cell 120. C0, C1, C2, and C3 indicated within the squares indicate the types of signal intensity obtained in the pixels per frame, and specifically correspond to C0, C1, C2, and C3 illustrated in FIG. 5.

In the exposure period, the voltage level of each of control lines TG1 to TG4 and control lines PRS1 to PRS4 alternates between a high level and a low level. That is, each of first transfer transistors 221 to 224 and second transfer transistors 231 to 234 is turned on and off alternately.

Here, the voltage levels of control lines TG1 to TG4 change in the same phase. That is, first transfer transistors 221 to 224 are simultaneously turned on and simultaneously turned off. Likewise, the voltage levels of control lines PRS1 to PRS4 change in the same phase. Second transfer transistors 231 to 234 are simultaneously turned on and simultaneously turned off.

Moreover, when one pixel is focused on, control line PRSn and control line TGn are changed to a high level or a low level exclusively from one another. In other words, the voltage level of control line PRSn and the voltage level of control line TGn have a relationship with a 180 degree phase reversal.

That is, within one pixel, on and off of the first transfer transistor and on and off of the second transfer transistor are mutually exclusive to one another. For instance, during the on-period of first transfer transistor 221, second transfer transistor 231 is off, and during the off-period of first transfer transistor 221, second transfer transistor 231 is on.

In each frame and in each pixel, at the timing when second transfer transistors 231 to 234 are turned off (control line PRSn is switched from the high level to the low level), it becomes possible to accumulate charge generated in photoelectric converters 211 to 214 (a charge accumulation period starts). The charge generated in photoelectric converters 211 to 214 is accumulated in charge accumulator FD (and capacitor 123) via first transfer transistors 221 to 224. At the timing when first transfer transistors 221 to 224 are turned off (control line TGn is switched from the high level to the low level), the accumulation of the charge generated in photoelectric converters 211 to 214 ends (the charge accumulation period ends). When first transfer transistors 221 to 224 are turned off, second transfer transistors 231 to 234 are turned on, which can reset the electric potentials of photoelectric converters 211 to 214 and nodes N1 to N4. In the embodiment, the charge accumulation period of each pixel is practically the same as the on-period of the first transfer transistor (or the off-period of the second transfer transistor).

In the example illustrated in FIG. 7A, the charge accumulation periods of frames 1 to 4 correspond to the first to fourth exposure sections illustrated in FIG. 5. Here, the length of the charge accumulation periods is half the period of irradiation light (corresponding to 180 degrees) and is so set that the phase shifts by 90 degrees per frame in the order of frames 1 to 4. Thus, there is no overlapping of the charge accumulation periods between frame 1 and frame 3, and there is no overlapping of the charge accumulation periods between frame 2 and frame 4.

As illustrated in FIG. 7B, during the respective charge accumulation periods of frames 1 to 4 (in the periods in which the signal level is a high level), each of signal intensities C0 to C3 is obtained according to the intensity of reflected light. In each frame period, the charge accumulation period is repeatedly set within the exposure period, even if the signal intensity obtained in each charge accumulation period is weak, a sufficient signal intensity can be obtained within the exposure period. Moreover, variations among the charge accumulation periods can be suppressed. Accordingly, the signal-to-noise (SN) ratio can be improved.

Moreover, in the first driving example, all of the four pixels, pixels 201 to 204 are used for detecting reflected light. Signal charge obtained in each of the four pixels, pixels 201 to 204 can be accumulated in charge accumulator FD. Thus, it is possible to suppress variations among the pixels, which makes it possible to further improve the SN ratio.

In this way, in the first driving example, the four pixels, pixels 201 to 204 included in unit cell 120 are exposed to reflected light L2 at a different timing per frame period. Within the frame period, the start timing of the exposure of the four pixels, pixels 201 to 204 is the same, and the end timing of the exposure of the four pixels is the same. Signal intensities C0 to C3 can be obtained within the exposure periods in the order of frames 1 to 4. Signal intensities C0 to C3 are read out from each of the plurality of unit cells 120 and output from imaging apparatus 100 to ISP 13 as sensor output data. Using signal intensities C0 to C3 per unit cell 120, ISP 13 can calculate, for each unit cell 120, the distance to target object 2 from Expressions (1) and (2) described above, and generate a range image.

It should be noted that in the instance illustrated in FIG. 7A, the voltage level of control line GC is maintained at a high level. That is, capacitor connection transistor 122 is constantly in an on-state, which leads to a state in which charge accumulator FD and capacitor 123 are connected. Thus, it possible to accumulate charge also in capacitor 123. Thus, it is possible to increase the accumulable amount of charge, which makes it possible to expand the dynamic range.

### <Second Driving Example>

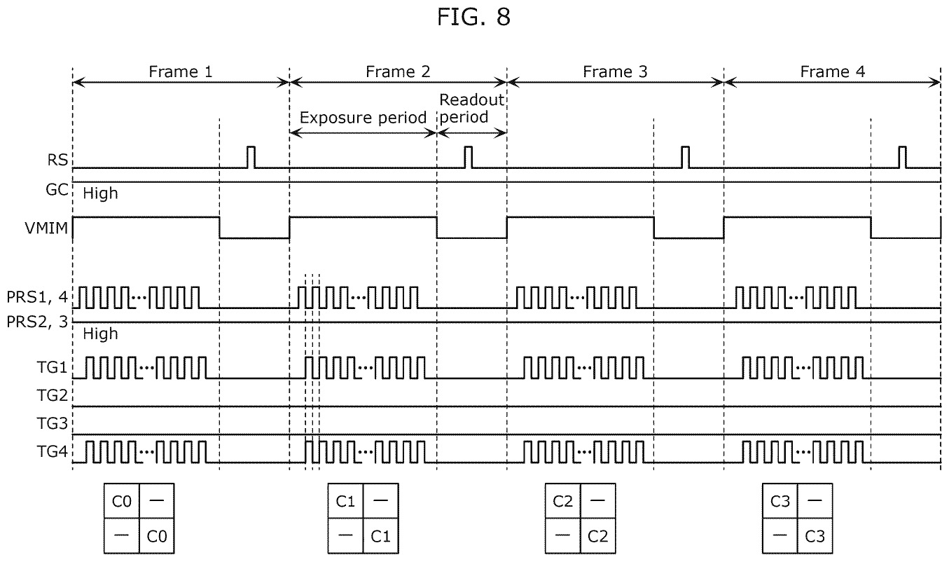

Next, a second driving example of imaging apparatus 100 in the CW-ToF method is described with reference to FIG. 8. In the second driving example, only two out of the four pixels, pixels 201 to 204 included in unit cell 120 are used for distance measurement.

FIG. 8 is a timing chart illustrating a second driving example of the distance measuring mode using the CW-ToF method. It should be noted that RS, GC, VMIM, PRS1 to PRS4, and TG1 to TG4 in FIG. 8 indicate the same things as those indicated in FIG. 7A. Hereinafter, the descriptions focus on the differences from the first driving example, and the explanations of common points are omitted.

In the second driving example, pixel 201 and pixel 204 are used for distance measurement, and pixel 202 and pixel 203 are not used. Specifically, during each frame period, the voltage levels of control lines PRS2 and PRS3 are maintained at a high level, and the voltage levels of control lines TG2 and TG3 are maintained at a low level, in order not to accumulate, in charge accumulator FD, charge generated in pixels 202 and 203. The temporal changes of the voltage levels of control lines PRS1 and PRS4 and control lines TG1 and TG4 are the same as those in the first driving example illustrated in FIG. 7A. Thus, signal charge generated in each of photoelectric converter 211 of pixel 201 and photoelectric converter 214 of pixel 204 in each of frames 1 to 4 is accumulated in charge accumulator FD.

It should be noted that in the second driving example, the instance in which only the two out of the four pixels are used is described as a non-limiting example. The number of pixels to be used may be only one or only three. That is, when unit cell 120 includes n pixels, only m pixels, where m is a natural number less than n, may be used in the distance measuring mode using the CW-ToF method. That is, in the distance measuring mode, the m pixels may be exposed to reflected light L2 rather than using all of the n pixels. Since it is possible decrease the number of pixels to be driven, it is possible to reduce the power consumption.

### <Third Driving Example>

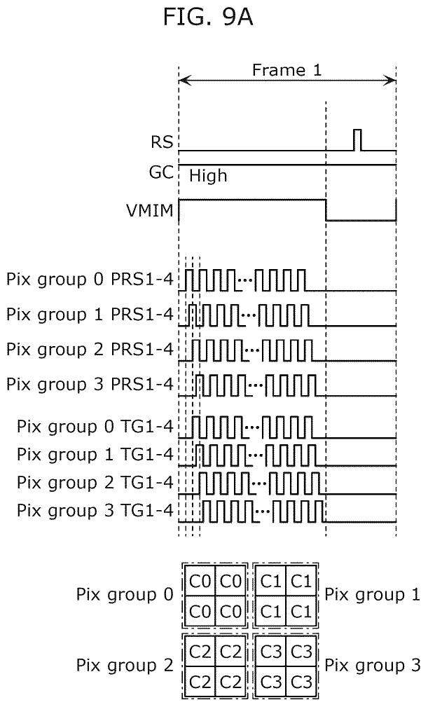

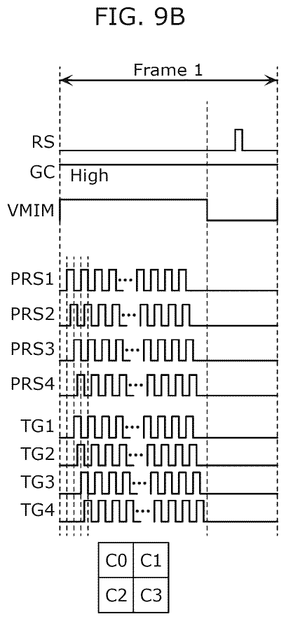

Next, a third driving example of imaging apparatus 100 in the CW-ToF method is described with reference to FIGS. 9A and 9B.

FIG. 9A is a timing chart illustrating a third driving example of the distance measuring mode using the CW-TOF method. It should be noted that RS, GC, VMIM, PRS1 to PRS4, and TG1 to TG4 in FIG. 9A indicate the same things as those indicated in FIG. 7A. Hereinafter, the descriptions focus on the differences from the first driving example, and the explanations of common points are omitted.

As illustrated in FIG. 9A, within one frame period, the charge accumulation period differs per Pix group (unit cell 120). Specifically, setting is such that the phase of the temporal change of the voltage level of control line PRSn, where n=1 to 4, shifts by 90 degrees per Pix group, in the order of Pix group 0, Pix group 1, Pix group 2, and Pix group 3. Within the Pix group (unit cell 120), the voltage level of PRSn, where n=1 to 4, changes in the same phase.

The same applies to control line TGn, where n=1 to 4. Setting is such that the phase of the temporal change of the voltage level of control line TGn, where n=1 to 4, shifts by 90 degrees per Pix group, in the order of Pix group 0, Pix group 1, Pix group 2, and Pix group 3. Within the Pix group (unit cell 120), the voltage level of TGn, where n=1 to 4, changes in the same phase.

Thus, since the charge accumulation period differs per unit cell 120 within the same frame period, it is possible to suppress motion blur from occurring.

It should be noted that in the embodiment, the instance in which charge accumulator FD is shared by the four pixels, pixels 201 to 204 is described. However, a charge accumulator (memory) may be provided within each pixel. In this case, as illustrated in FIG. 9B, it is possible to make the charge accumulation period of each pixel differ within one frame period. That is, within the frame period, it is possible to make the start timing of exposure of each of the four pixels differ and the end timing of exposure of each of the four pixels differ. FIG. 9B is a timing chart illustrating a variation example of the third driving example of the distance measuring mode using the CW-ToF method.

Specifically, the temporal change of each of the voltage levels of control lines PRS1 to PRS4 is so set that the phase shifts by 90 degrees per control signal in the order stated. Specifically, the temporal change of each of the voltage levels of control lines TG1 to TG4 is so set that the phase shifts by 90 degrees per control signal in the order stated. Also in this case, it is possible to suppress motion blur.

### [Pulse ToF Method]

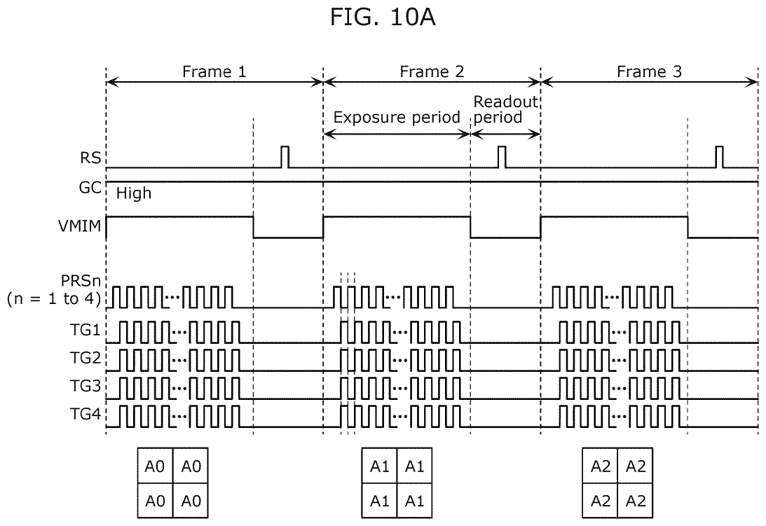

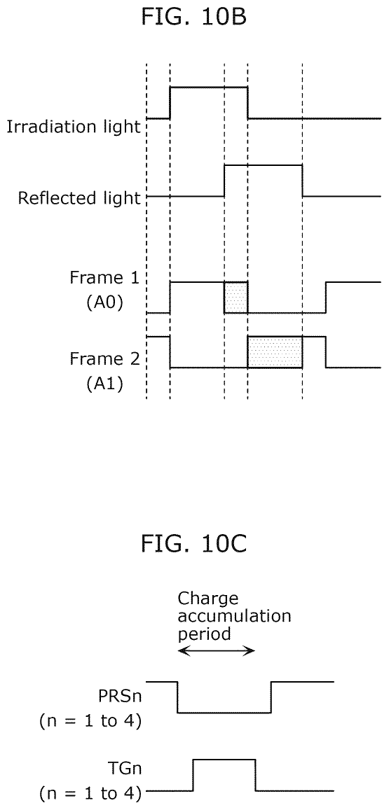

Next, a specific operation of imaging apparatus 100 in a distance measuring mode using the pulse ToF method is described with reference to FIGS. 10A, 10B, and 10C.

FIG. 10A is a timing chart illustrating a driving example of a distance measuring mode using the pulse ToF method. FIG. 10B illustrates a relationship between irradiation light and reflected light and each frame period in the example illustrated in FIG. 10A. FIG. 10C illustrates examples of control signals supplied to the two transfer transistors in the example illustrated in FIG. 10A. It should be noted that RS, GC, VMIM, PRS1 to PRS4, and TG1 to TG4 in FIG. 10A indicate the same things as those indicated in FIG. 7A. Hereinafter, the descriptions focus on the differences from the first driving example using the CW-ToF method, and the explanations of common points are omitted.

As illustrated in FIG. 10A, the charge accumulation periods of frames 1 to 3 correspond to the first to third exposure sections illustrated in FIG. 6. Specifically, as illustrated in FIG. 10B, in frame 1, the charge accumulation period is set to the same section as the irradiation light (pulse light) irradiation section. In frame 2, the charge accumulation period is set to the section that starts simultaneously with the stop of irradiation of the irradiation light. In frame 3, the charge accumulation period is set to the section in which reflected light is not present. That is, in frame 3, emission of light from light source 11 is stopped. The length of the charge accumulation period in each frame is the same as the pulse width of the irradiation light. In frame 3, signal intensity A2 of background light (corresponding to background light component BG in FIG. 6) is obtained. By using signal intensity A2 of the background light, it is possible to obtain signal intensity A0 of the reflected light from a detection result in frame 1 and signal intensity A1 of the reflected light from a detection result in frame 2. Using obtained signal intensities A0 and A1, the distance to target object 2 can be calculated for each unit cell 120 from Expression (3) described above, and a range image can be generated.

It should be noted that as illustrated in FIG. 10C, the charge accumulation period is a period from the timing when second transfer transistors 231 to 234 are turned off (control line PRSn is switched from a high level to a low level) until the timing when first transfer transistors 221 to 224 are turned off (control line TGn is switched from a high level to a low level).

As illustrated in FIG. 10C, the timing when the voltage level of control line TGn rises is delayed from the timing when the voltage level of control line PRSn falls. Moreover, the timing when the voltage level of control line PRSn rises is delayed from the timing when the voltage level of control line TGn falls. This can suppress first transfer transistors 221 to 224 and second transfer transistors 231 to 234 from being simultaneously in an on-state. Since it is possible to suppress charge from unexpectedly flowing into or out from charge accumulator FD, it is possible to enhance the accuracy of distance measurement. Such a driving method can also be used in the CW-ToF method.

Also in the pulse ToF method, a part of the four pixels included in unit cell 120 need not be used. That is, when unit cell 120 includes n pixels, only m pixels, where m is a natural number less than n, may be used in the distance measuring mode using the pulse ToF method. It is possible to reduce the power consumption by decreasing the number of pixels to be driven.

### [RGB Mode]

Next, a specific operation of imaging apparatus 100 in the RGB mode is described.

### <First Driving Example>

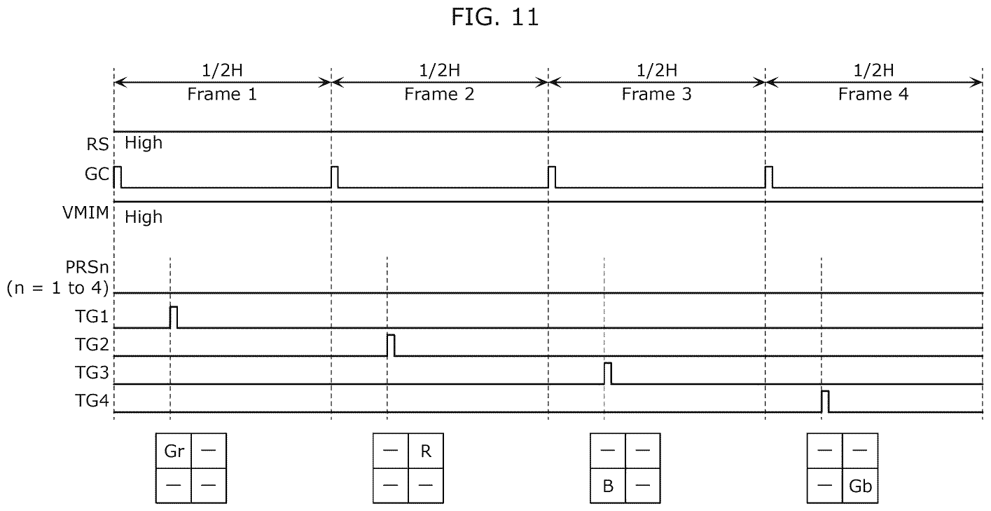

First, a first driving example of imaging apparatus 100 in the RGB mode is described with reference to FIG. 11. In the first driving example, capacitor connection transistor 122 is used to reset charge accumulator FD.

FIG. 11 is a timing chart illustrating a first driving example of the RGB mode. RS, GC, VMIM, PRS1 to PRS4, and TG1 to TG4 in FIG. 11 indicate the same things as those indicated in FIG. 7A. Hereinafter, the descriptions focus on the differences from the first driving example using the CW-ToF method, and the explanations of common points are omitted.

Period ½H illustrated in FIG. 11 is a period having half the length of horizontal period H (½ horizontal period), and corresponds to a frame period in the distance measuring mode. Horizontal period H is a period in which to read out pixels arranged in the row direction among the pixels of imaging apparatus 100.

In the example illustrated in FIG. 11, the electric potential of charge accumulator FD is reset by changing the voltage level of control line GC to a high level at the beginning of the ½ horizontal period. It should be noted that since the voltage level of control line RS is maintained at a high level, reset transistor 121 is maintained in a conducting state (on-state). Thus, turning on capacitor connection transistor 122 can lead to conduction between charge accumulator FD and power supply line AVDDP. It should be noted that power supply line VMIM is maintained at a certain voltage level. The voltage level of power supply line VMIM is maintained at, for example, the voltage level of power supply line AVDDP. It should be noted that the voltage level of power supply line VMIM is not limited to a particular voltage level and may be maintained at 0 V, for example.

In the RGB mode, the voltage level of control line PRSn is maintained at a low level. The voltage levels of control lines TG1 to TG4 are maintained at a low level except for the predetermined pulse periods (the charge accumulation periods). For instance, in frame 1, when the voltage level of control line TG1 is changed to a high level, first transfer transistor 221 is turned on. In this way, charge generated in photoelectric converter 211 (corresponding to the intensity of green light) is accumulated in charge accumulator FD. Although the readout of the charge accumulated in charge accumulator FD is not illustrated in FIG. 11, after the voltage level of control line TG1 is switched from the high level to the low level, selection transistor 125 is turned on at a predetermined timing in the period, within frame 1, in which the voltage level is maintained at the low level, and then the charge is read out to vertical signal line 160.

In frame 2, first transfer transistor 222 is turned on by changing the voltage level of control line TG2 to a high level. In this way, charge generated in photoelectric converter 212 (corresponding to the intensity of red light) is accumulated in charge accumulator FD, and then read out. In frame 3, first transfer transistor 223 is turned on by changing the voltage level of control line TG3 to a high level. In this way, charge generated in photoelectric converter 213 (corresponding to the intensity of blue light) is accumulated in charge accumulator FD, and then read out. In frame 4, first transfer transistor 224 is turned on by changing the voltage level of control line TG4 to a high level. In this way, charge generated in photoelectric converter 214 (corresponding to the intensity of green light) is accumulated in charge accumulator FD, and then read out.

In this way, respective RGB signal intensities can be obtained from unit cell 120. RGB signal intensities are read out from each of the plurality of unit cells 120 and output from imaging apparatus 100 to ISP 13 as sensor output data. ISP 13 can generate an RGB image, using the RGB signal intensities per unit cell 120.

In the first driving example, a signal is read out in an off-state of capacitor connection transistor 122, and charge accumulator FD is reset by turning on capacitor connection transistor 122. Signal readout at a high gain is achieved by setting the capacitance component connected to the gate of readout transistor 124 to the small capacitance of only charge accumulator FD.

### <Second Driving Example>

Next, a second driving example of imaging apparatus 100 in the RGB mode is described with reference to FIG. 12. In the second driving example, reset transistor 121 is used to reset charge accumulator FD.

FIG. 12 is a timing chart illustrating a second driving example of the RGB mode. RS, GC, VMIM, PRS1 to PRS4, and TG1 to TG4 in FIG. 12 indicate the same things as those indicated in FIG. 7A. Hereinafter, the descriptions focus on the differences from the first driving example using the CW-ToF method, and the explanations of common points are omitted.

In the example illustrated in FIG. 12, the electric potential of charge accumulator FD is reset by changing the voltage level of control line RS to a high level at the beginning of the ½ horizontal period. It should be noted that since the voltage level of control line GC is maintained at a high level, capacitor connection transistor 122 is maintained in a conducting state (on-state). Thus, turning on reset transistor 121 can lead to conduction between charge accumulator FD and power supply line AVDDP. It should be noted that power supply line VMIM is maintained at a certain voltage level. The voltage level of power supply line VMIM is maintained at, for example, the voltage level of power supply line AVDDP. It should be noted that the voltage level of power supply line VMIM is not limited to a particular voltage level and may be maintained at 0 V, for example.

In the second driving example, capacitor connection transistor 122 is maintained in an on-state. A signal is read out in an off-state of reset transistor 121, and charge accumulator FD is reset by turning on reset transistor 121. The capacitance component connected to the gate of readout transistor 124 can be increased using charge accumulator FD and capacitor 123, which enables signal readout at a low gain. Because of the lower gain, it is possible to read out a saturation signal without deviating from the dynamic range of the subsequent circuit.

### [Capacitor]

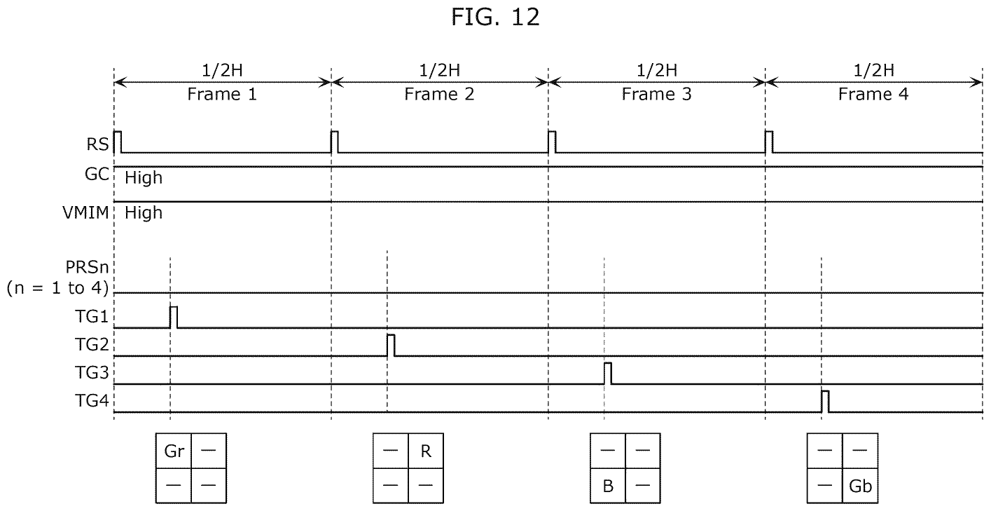

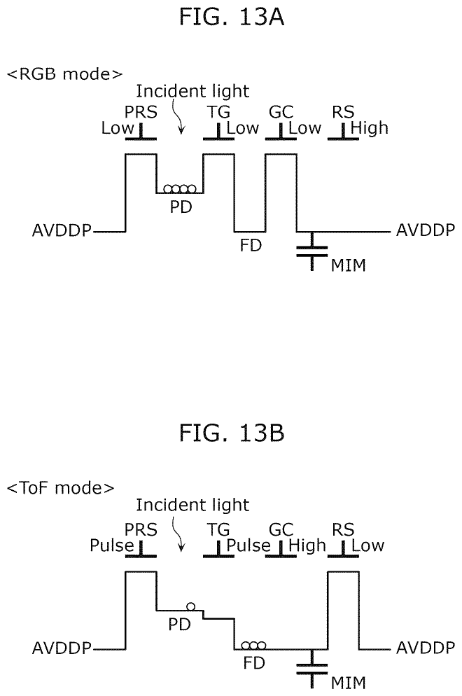

Then, the functions of capacitor 123 are described with reference to FIGS. 13A and 13B.

FIG. 13A illustrates an electric potential within unit cell 120 in the RGB mode. FIG. 13B illustrates an electric potential within unit cell 120 in the ToF mode.

In FIGS. 13A and 13B, PRS, TG, GC, and RS correspond to control lines PRS, TG, GC, and RS, respectively, and indicate the gate of second transfer transistor 231 (or one of second transfer transistors 232 to 234), the gate of first transfer transistor 221 (or one of first transfer transistors 222 to 224), the gate of capacitor connection transistor 122, and the gate of reset transistor 121, respectively. Low indicates that the voltage level of a corresponding control line is a low level, which means that a corresponding transistor is in an off-state. High indicates that the voltage level of a corresponding control line is a high level, which means that a corresponding transistor is in an on-state. Pulse means that a signal alternating between a high level and a low level is supplied. PD indicates photoelectric converter 211 (or one of photoelectric converters 212 to 214), FD indicates charge accumulator FD, and MIM indicates capacitor 123. The circles shown near PD and FD indicate signal charges.

In the RGB mode, as illustrated in FIG. 13A, during the exposure period of photoelectric converter 211, first transfer transistor 221 and second transfer transistor 231 are in an off-state. Thus, generated signal charge is accumulated in, for example, photoelectric converter 211 and node N1. In reading out a signal, after first transfer transistor 221 is turned on, selection transistor 125 (not illustrated) is turned on, thereby reading out the signal to vertical signal line 160. In the RGB mode, noise can be suppressed by reading out the signal at a high gain without using capacitor 123.

Meanwhile, in the ToF mode, capacitor connection transistor 122 is maintained in an on-state. Thus, as illustrated in FIG. 13B, signal charge generated in photoelectric converters 211 to 214 is accumulated in charge accumulator FD and capacitor 123. High saturation can be achieved because of an increase in the accumulation amount of charge.

In this way, in the embodiment, in the ToF mode, capacitor connection transistor 122 maintains conduction between capacitor 123 and charge accumulator FD, and in the RGB mode, capacitor connection transistor 122 interrupts conduction between capacitor 123 and charge accumulator FD. Thus, it is possible to achieve both highly accurate distance measurement and obtainment of a high-definition RGB image.

### [Relationship Between Transfer Transistors and Control Lines]

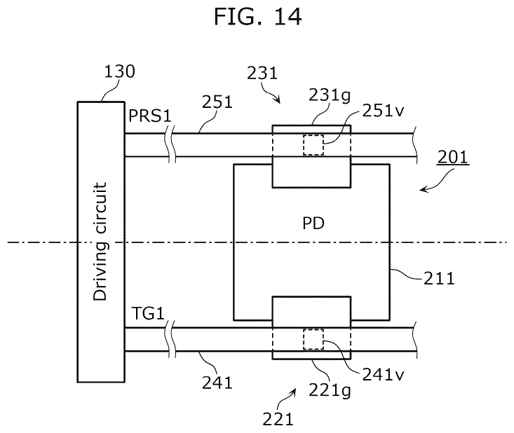

Next, a relationship between the first transfer transistor and the second transfer transistor in each pixel and the control signals connected the gates thereof is described with reference to FIG. 14. Although the explanations of pixel 201 are given below, the same applies to pixels 202 to 204.

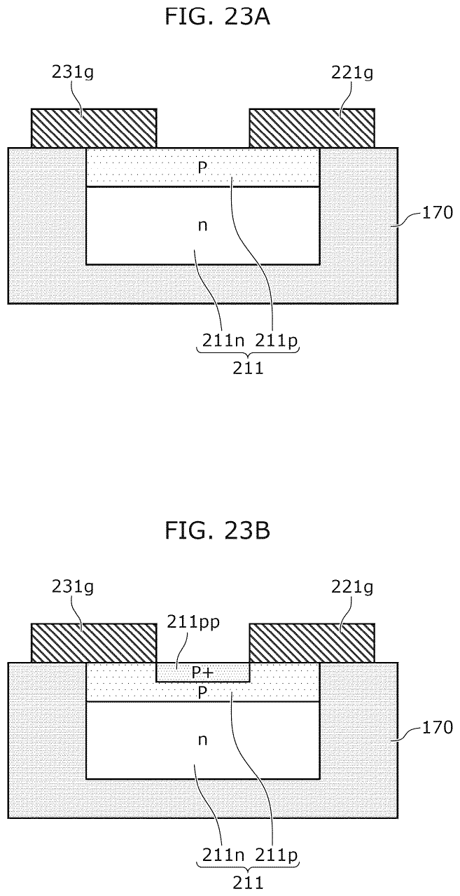

FIG. 14 is a schematic plan view illustrating an example of pixel 201 according to the embodiment. In a plan view, photoelectric converter 211 is, for example, rectangular (square or rectangular). Photoelectric converter 211 includes a p-type semiconductor region and an n-type semiconductor region that are provided in the semiconductor substrate (see FIG. 23A described later). The n-type semiconductor region and the p-type semiconductor region are stacked on one another in the thickness direction of the substrate. The p-type semiconductor region is provided closer to the surface (top surface) of the semiconductor substrate than the n-type semiconductor region is.

As illustrated in FIG. 14, in a plan view, gate 221g of first transfer transistor 221 and gate 231g of second transfer transistor 231 overlap photoelectric converter 211. An insulator film (not illustrated) is provided between gate 221g and photoelectric converter 211 (the p-type semiconductor region) and between gate 231g and photoelectric converter 211 (the p-type semiconductor region). Each of gates 221g and 231g is formed using a conductive material such as a metal or conductive polysilicon. In a plan view, each of gates 221g and 231g is rectangular. However, the plan view shape is not limited to a rectangular shape. In the embodiment, gates 221g and 231g are the same in terms of the material, shape, and size.

It should be noted that the meaning of the same size encompasses not only the case where the areas (or volumes) of the gates are exactly the same, but also the case where a difference between the areas (or volumes) of the gates is 5% or less of the area (or volume) of one of the gates. Moreover, the meaning of the same shape encompasses not only the case where the shapes of the gates are exactly the same, but also the case where a difference in area (or volume) due to the difference between the shapes of the gates is 5% or less of the area (or volume) of one of the gates. Moreover, the meaning of the same material encompasses not only the case where materials have exactly the same composition ratio but also the case where a difference in composition ratio is 5% or less of the composition ratio of one of the gates. For instance, when differences in size, shape, material caused due to manufacturing errors and a difference in composition ratio caused due to impurities that inevitably got in during manufacture are caused, the above features of the gates are considered “the same”. In the above, the differences are set to 5% or less in consideration of manufacturing errors at present, for example. However, if errors can be permitted as manufacturing factors or design elements, the differences are not necessarily limited to 5% or less. The above explanations apply not only to gates 221g and 231g but also to the materials, shapes, and sizes of other constituent elements (for example, the control lines described later).

Gate 221g is connected to driving circuit 130 via line 241 and via 241v. Specifically, line 241 is disposed above gate 221g with an interlayer insulation film (not illustrated) interposed therebetween such that line 241 overlaps gate 221g in a plan view. Via 241v passes through the interlayer insulation film and connects line 241 and gate 221g. Line 241 and via 241v constitute control line TG1, which is an example of the first control line.

Gate 231g is connected to driving circuit 130 via line 251 and via 251v. Specifically, line 251 is disposed above gate 231g with the interlayer insulation film (not illustrated) interposed therebetween such that line 251 overlaps gate 231g in a plan view. Via 251v passes through the interlayer insulation film and connects line 251 and gate 231g. Line 251 and via 251v constitute control line PRS1, which is an example of the second control line.

In the embodiment, the load on control line TG1 is equal to the load on control line PRS1. Specifically, the load on control line TG1 from driving circuit 130 to gate 221g is equal to the load on control line PRS1 from driving circuit 130 to gate 231g. The load on the control signal is the parasitic resistance and parasitic capacitance (RC components) of the control signal. Specifically, the RC components of line 241 and via 241v are equal to those of line 251 and via 251v.

It should be noted that the meaning of the equal loads (RC components) encompasses not only the case where the loads thereof are exactly the same, but also the case where a difference in the loads thereof is 5% or less of one of the loads. It should be noted that if an error can be permitted as a manufacturing factor or a design element, the difference is not necessarily limited to 5% or less.

For instance, control line TG1 and control line PRS1 are made of the same material and have the same shape and size. Specifically, line 241 and line 251 are made of the same material and have the same shape and size. Via 241v and via 251v are made of the same material and have the same shape and size. By making the lines/the vias be made of the same material and have the same shape and size, it is possible to readily equalize the loads applied to the lines and the loads applied to the vias. That is, material selection and design layout to equalize the loads can be readily performed.

In the embodiment, in a plan view of unit cell 120, (i) control line TG1 and first transfer transistor 221 and (ii) control line PRS1 and second transfer transistor 231 are symmetrically disposed with respect to the axis that is the straight line (the long dashed short dashed line illustrated in FIG. 14) passing through the center of photoelectric converter 211. The line symmetric layout can readily equalize the load on control line TG1 and the load on control line PRS1. That is, design layout to equalize the loads can be readily performed.

The load on the control line can be a factor that blunts the waveform of a control signal to be output from driving circuit 130. Especially in the ToF mode, control line TG1 and control line PRS1 alternate between a high level and a low level at a high speed in a mutually exclusive manner. Thus, if one of the waveforms is blunted more than the other waveform, a difference in the accumulation amounts of charge is caused, which may lead to a decrease in the accuracy of distance measurement.

By contrast, in the embodiment, the load on control line TG1 is equal to the load on control line PRS1. Thus, even if the waveform blunting of a control signal output from driving circuit 130 is caused, it is possible to decrease a blunting difference between control line TG1 and control line PRS1. Accordingly, it is possible to suppress the accuracy of distance measurement from decreasing.

Moreover, in the embodiment, the number of effective pixels connected to control line TG1 is equal to that of effective pixels connected to control line PRS1. This can readily equalize the load on control line TG1 and the load on control line PRS1, and thus suppress the accuracy of distance measurement from decreasing.

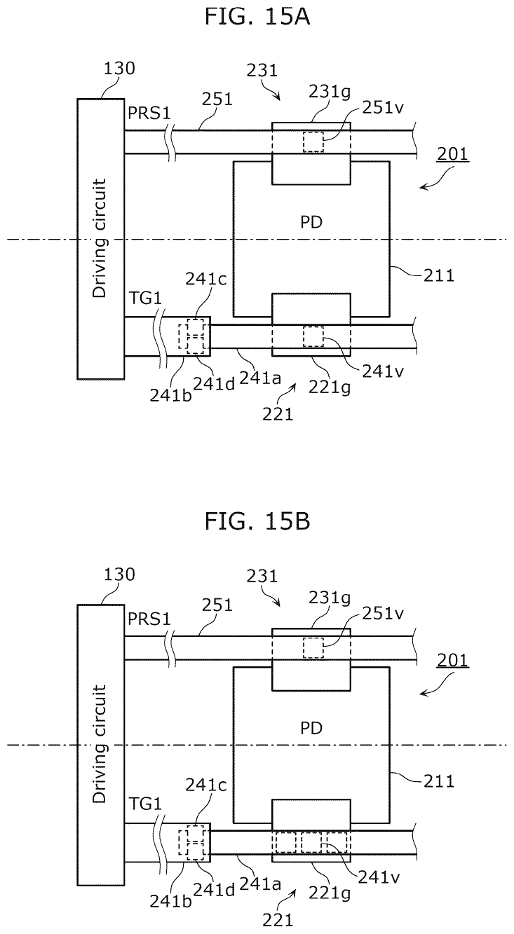

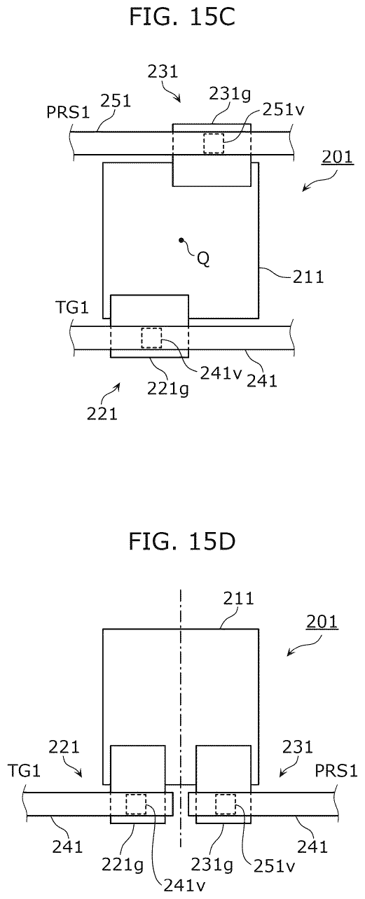

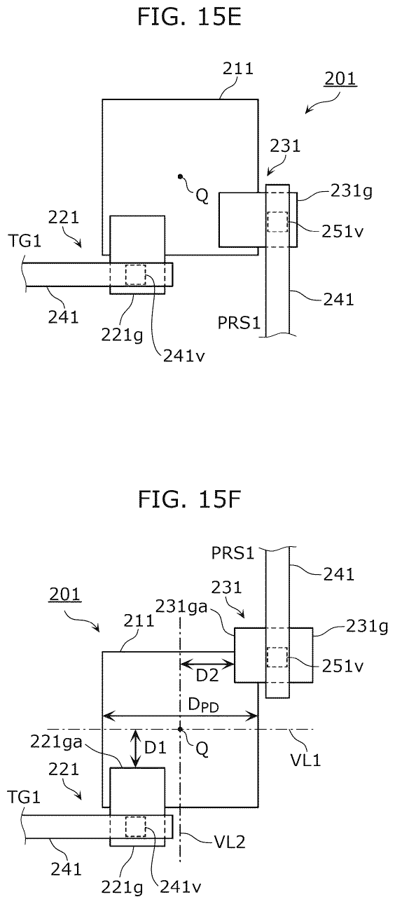

It should be noted that FIG. 14 illustrates, as a non-limiting example, the instance in which control line TG1 and control line PRS1 are made of the same material, have the same shape and size, and are disposed line-symmetrically. As illustrated in FIG. 15A, control line TG1 and control line PRS1 may have different shapes.

FIG. 15A is a schematic plan view illustrating another example of pixel 201 according to the embodiment. In the instance illustrated in FIG. 15A, gate 221g of first transfer transistor 221 is connected to driving circuit 130 via lines 241a and 241b and vias 241v, 241c, and 241d.

Line 241b is positioned at a height different from that of line 241a, and is connected to line 241a via vias 241c and 241d. For instance, it may not be possible to dispose control line TG1 and control line PRS1 at the same height (in the same layer) due to, for example, another line or an electrode being disposed. The instance illustrated in FIG. 15A is an example suitable for such a case.

It should be noted that if a control line includes two or more lines positioned at different heights, the line that has the largest proportion in the total distance from driving circuit 130 to the first transfer transistor or the second transfer transistor is referred to as a main line. For instance, in FIG. 15A, in the total distance from driving circuit 130 to gate 221g, when the distance ratio of line 241a to line 241b is 1 to 9, the main line of control line TG1 is line 241b. For instance, in the instance illustrated in FIG. 14, the main line of control line TG1 is line 241, and the main line of control line PRS1 is line 251. The heights of line 241 and line 251 are the same. Meanwhile, FIG. 15A illustrates an instance in which the height of line 241b, which is the main line of control line TG1, differs from the height of line 251, which is the main line of control line PRS1.

The path of control line TG1 is longer than that of control line PRS1. Normally, the longer the path, the larger the line resistance. Thus, line 241b is thicker than line 241a. That is, the line resistance of line 241b can be decreased by making the cross-sectional area of line 241b larger than that of line 241a. In this way, by adjusting the line resistance, it is possible to equalize the load on control line TG1 and the load on control line PRS1. It should be noted that by using different materials as the materials of control line TG1 and control line PRS1, the load on control line TG1 and the load on control line PRS1 may be equalized. As long as the load on control line TG1 and the load on control line PRS1 can be equalized, a specific achievement method is not limited to a particular method.

Each of FIGS. 15B to 15F is a schematic plan view illustrating another example of pixel 201 according to the embodiment. In the instance illustrated in FIG. 15B, the number of vias 241v differs from that of vias 251v. The number of vias 241v is an example of the number of first contacts that connect the first control line (control line TG1) and first transfer transistor 221. The number of vias 251v is an example of the number of second contacts that connect the second control line (control line PRS1) and second transfer transistor 231. In the instance illustrated in FIG. 15B, the number of vias 241v is three, whereas the number of vias 251v is one. It should be noted that the number of vias 241v and the number of vias 251v may be the same, and the shapes thereof may be different. Alternatively, via 241v and via 251v may be different in terms of both the number of vias and shape.

In this way, by making the number of contacts differ, the loads on the two control lines, control line TG1 and control line PRS1 can be adjusted. Since it is possible to decrease a difference in the waveform blunting of control signals transmitted through the two control lines, control line TG1 and control line PRS1, it is possible to suppress the accuracy of distance measurement from decreasing.

Moreover, in the instance illustrated in FIG. 15C, in a plan view of unit cell 120, each of (i) control line TG1 and first transfer transistor 221 and (ii) control line PRS1 and second transfer transistor 231 is disposed at the position reached by rotating (i) or (ii) by 180 degrees about center Q of photoelectric converter 211. That is, first transfer transistor 221 and second transfer transistor 231 have a point symmetrical positional relationship and shapes in which center Q of photoelectric converter 211 serves as the symmetrical center.

In the instance illustrated in FIG. 15D, in a plan view of unit cell 120, (i) control line TG1 and first transfer transistor 221 and (ii) control line PRS1 and second transfer transistor 231 are symmetrically disposed with respect to the axis that is the straight line (the long dashed short dashed line illustrated in FIG. 15D) passing through the center of photoelectric converter 211. In the instance illustrated in FIG. 15D, gate 221g of first transfer transistor 221 and gate 231g of second transfer transistor 231 overlap one side (the same side) out of the four sides of photoelectric converter 211 that is rectangular in a plan view. In this way, first transfer transistor 221 and second transfer transistor 231 may be disposed at the positions on one side relative to the center of photoelectric converter 211.

In the instance illustrated in FIG. 15E, in a plan view of unit cell 120, (i) control line TG1 and first transfer transistor 221 and (ii) control line PRS1 and second transfer transistor 231 are disposed at the positions reached by rotation of 90 degrees about center Q of photoelectric converter 211 from the position of the other. Specifically, control line TG1 and first transfer transistor 221 are disposed at the position reached by rotating control line PRS1 and second transfer transistor 231 clockwise by 90 degrees. It should be noted that the direction of rotation may be counterclockwise.

In the figures, only first transfer transistor 221 and second transfer transistor 231 may be symmetrically disposed with respect to the axis that is the straight line passing through the center of photoelectric converter 211, or may be disposed at the positions reached by rotation of 90 degrees or 180 degrees about center Q of photoelectric converter 211 from the position of the other transistor. That is, control line TG1 and control line PRS1 need not be disposed symmetrically with respect to the axis that is the straight line passing through the center of photoelectric converter 211, and need not be disposed at the positions reached by rotation of 90 degrees or 180 degrees about center Q of photoelectric converter 211 from the position of the other control line.

Moreover, in the instance illustrated in FIG. 15F, first transfer transistor 221 and second transfer transistor 231 do not have a symmetrical relationship, and control line TG1 and control line PRS1 do not have a symmetrical relationship. In the instance illustrated in FIG. 15F, in a plan view, at least one of distance D1 between first side 221ga of gate 221g and first straight line VL1 or distance D2 between second side 231ga of gate 231g and second straight line VL2 is less than length D_{pd} of one side of photoelectric converter 211. It should be noted that first side 221ga is the closest to center Q of photoelectric converter 211 among the four sides of gate 221g. Second side 231ga is the closest to center Q of photoelectric converter 211 among the four sides of gate 231g. First straight line VL1 is a line passing through center Q of photoelectric converter 211 and parallel to first side 221ga. Second straight line VL2 is a line passing through center Q of photoelectric converter 211 and parallel to second side 231ga. It should be noted that as a non-limiting example, length D_{pd} is the length of the shortest side among the four sides of photoelectric converter 211.

Thus, the positions of gates 221g and 231g can be adjusted such that gates 221g and 231g are not too far away from photoelectric converter 211. That is, it becomes possible to adjust a load such as parasitic capacitance. Since it is possible to decrease a difference in the waveform blunting of control signals transmitted through the two control lines, control line TG1 and control line PRS1, it is possible to suppress the accuracy of distance measurement from decreasing.

As illustrated in FIGS. 15A to 15F, the load on control line TG1 and the load on control line PRS1 may be equalized by appropriately adjusting the positions of the control lines and the transistors according to, for example, the materials, shapes, and sizes of control lines TG1 and PRS1, first transfer transistor 221, and second transfer transistor 231, and then disposing the elements. That is, as long as the load on control line TG1 and the load on control line PRS1 can be equalized, a specific achievement method is not limited to a particular method.

### [Specific Configuration and Operation of Driving Circuit]

Then, a specific configuration and operation of driving circuit 130 are described. It should be noted that in the following explanations, pixel 201 out of the pixels to be controlled by driving circuit 130 is used as an example. Since the explanations of pixel 201 also apply to pixels 202 to 204, the explanations thereof are omitted.

### <Configuration>

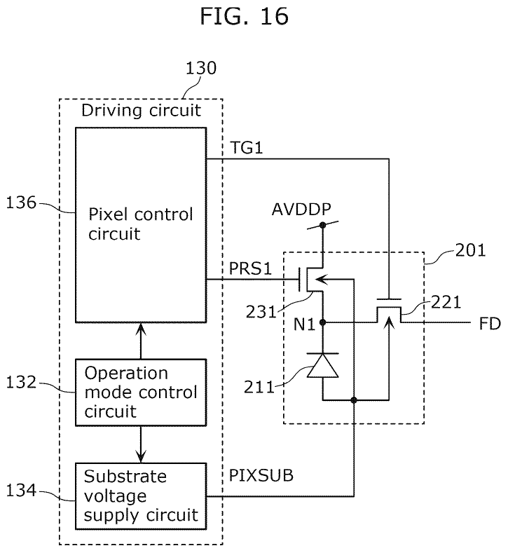

First, a configuration of driving circuit 130 is described with reference to FIGS. 16 and 17. FIG. 16 illustrates a configuration of driving circuit 130 according to the embodiment. FIG. 17 illustrates circuit configurations of pixel control circuit 136 and substrate voltage supply circuit 134 according to the embodiment.

Driving circuit 130 according to the embodiment supplies a voltage corresponding to the operation mode selected from among the operation modes to substrate 170, the first control terminal of the first transfer transistor, or the second control terminal of the second transfer transistor. Specifically, driving circuit 130 changes the voltage level of a voltage to be supplied to substrate 170, according to the operation mode. Moreover, driving circuit 130 changes, according to the operation mode, the magnitude (the electric potential) of at least one of the high level or the low level of a voltage supplied to each of the gate of the first transfer transistor and the gate of the second transfer transistor.

As illustrated in FIG. 16, driving circuit 130 includes operation mode control circuit 132, substrate voltage supply circuit 134, and pixel control circuit 136.

Operation mode control circuit 132 is an example of a mode control circuit, and controls substrate voltage supply circuit 134 and pixel control circuit 136 according to the operation mode. Specifically, operation mode control circuit 132 outputs, to substrate voltage supply circuit 134, a first control signal corresponding to the operation mode selected from among the operation modes. Moreover, operation mode control circuit 132 outputs, to pixel control circuit 136, a second control signal corresponding to the operation mode selected from among the operation modes.

Substrate voltage supply circuit 134 is an example of a first voltage supply circuit and supplies a voltage to substrate 170. Substrate voltage supply circuit 134 can change the value (voltage level) of a voltage supplied to substrate 170, in accordance with the first control signal output from operation mode control circuit 132. As illustrated in FIG. 17, substrate voltage supply circuit 134 includes first connection circuit 321 and the two signal lines, signal lines 311 and 312.

Signal line 311 is an example of a first signal line set to a first electric potential. The first electric potential is, for example, the ground electric potential (0 V). Signal line 311 is a ground line set to the ground electric potential.

Signal line 312 is an example of a second signal line set to a second electric potential different from the first electric potential. Specifically, the second electric potential is an electric potential lower than the first electric potential. As a non-limiting example, the second electric potential is-1 V.

First connection circuit 321 switches between signal lines 311 and 312 according to the operation mode, and connects signal line 311 or 312 to substrate 170. In the embodiment, first connection circuit 321 switches between signal lines 311 and 312 according to the first control signal, and connects signal line 311 or 312 to substrate 170. Specifically, when the imaging mode is selected, first connection circuit 321 connects signal line 311 to substrate 170. When the distance measuring mode is selected, first connection circuit 321 connects signal line 312 to substrate 170.

As illustrated in FIG. 17, first connection circuit 321 includes the two switching devices, switching device 301 and switching device 302. For instance, each of switching devices 301 and 302 is a field-effect transistor (FET) including a gate, a source, and a drain.

Switching device 301 switches between conduction and nonconduction between signal line 311 and substrate 170. The gate of switching device 301 is connected to operation mode control circuit 132, and receives the first control signal as input. One of the source or drain of switching device 301 is connected to signal line 311. The other of the source or drain of switching device 301 is connected to substrate 170.

Switching device 302 switches between conduction and nonconduction between signal line 312 and substrate 170. The gate of switching device 302 is connected to operation mode control circuit 132 via inverter 135, and receives the first control signal as input. One of the source or drain of switching device 302 is connected to signal line 312. The other of the source or drain of switching device 302 is connected to substrate 170.

The inversion signal of the first control signal to be input to the gate of switching device 301 is input to the gate of switching device 302 via inverter 135. Thus, switching devices 301 and 302 perform mutually exclusive operations. Specifically, when switching device 301 is on, switching device 302 is off, whereas when switching device 302 is on, switching device 301 is off.

Pixel control circuit 136 is an example of a second voltage supply circuit, and supplies a voltage to at least one of gate 221g of first transfer transistor 221 or gate 231g of second transfer transistor 231. Pixel control circuit 136 can change the value (voltage level) of a voltage supplied to each of gates 221g and 231g, in accordance with the second control signal output from operation mode control circuit 132. As illustrated in FIG. 17, pixel control circuit 136 includes second connection circuit 322 and signal lines 313a, 313b, 314a, and 314b.

Signal lines 313a and 313b are examples of one or more third signal lines set to at least one of a third electric potential or a fourth electric potential higher than the third electric potential. Specifically, signal line 313a is set to the third electric potential (a low level). As a non-limiting example, the third electric potential is −1.4 V. The third electric potential may be, for example, −1 V. Although signal line 313a is identical to signal line 312 in the embodiment, signal line 313a may differ from signal line 312. Signal line 313b is set to the fourth electric potential (a high level). As a non-limiting example, the fourth electric potential is 3.3 V. The fourth electric potential may be, for example, 2.8 V or 3.8 V.

Signal lines 314a and 314b are examples of one or more fourth signal lines set to at least one of a fifth electric potential or a sixth electric potential higher than the fifth electric potential. Specifically, signal line 314a is set to the fifth electric potential (a low level). The fifth electric potential is, for example, the ground electric potential (0 V). Signal line 314a is a ground line set to the ground electric potential. Signal line 314a may be identical to signal line 311. Signal line 314b is set to the sixth electric potential (a high level). As a non-limiting example, the sixth electric potential is 2 V. The sixth electric potential may be, for example, 1.2 V.

It should be noted that signal line 314a is also an example of a seventh signal line set to a seventh electric potential and signal line 313a is also an example of an eighth signal line set to an eighth electric potential. The eighth electric potential in this case is an electric potential lower than the seventh electric potential, and corresponds to the above-mentioned third electric potential (for example, −1.4 V). The seventh electric potential in this case corresponds to the above-mentioned fifth electric potential (for example, 0 V).

Moreover, signal line 313b is also an example of the seventh signal line set to the seventh electric potential and signal line 314b is also an example of the eighth signal line set to the eighth electric potential. The eighth electric potential in this case is an electric potential lower than the seventh electric potential, and corresponds to the above-mentioned sixth electric potential (for example, 2 V). The seventh electric potential in this case corresponds to the above-mentioned fourth electric potential (for example, 3.3 V).

In the embodiment, an electric potential difference between the fourth electric potential and the third electric potential differs from an electric potential difference between the sixth electric potential and the fifth electric potential. Specifically, the electric potential difference between the fourth electric potential and the third electric potential is larger than the electric potential difference between the sixth electric potential and the fifth electric potential. As an example, the electric potential difference between the fourth electric potential and the third electric potential is at least twice the electric potential difference between the sixth electric potential and the fifth electric potential, and may be at least three times the electric potential difference between the sixth electric potential and the fifth electric potential.

Second connection circuit 322 switches between signal lines 313a and 313b and signal lines 314a and 314b according to the operation mode, and connects signal lines 313a and 313b or signal lines 314a and 314b to at least one of gate 221g or gate 231g. In the embodiment, second connection circuit 322 switches between signal lines 313a and 313b and signal lines 314a and 314b according to the second control signal, and connects signal lines 313a and 313b or signal lines 314a and 314b to gates 221g and 231g. Specifically, when the imaging mode is selected, second connection circuit 322 connects signal lines 313a and 313b to gates 221g and 231g. Specifically, second connection circuit 322 connects one of signal line 313a or 313b to one of gate 221g or 231g, and the other of signal line 313a or 313b to the other of gate 221g or 231g. That is, it prevents signal lines 313a and 313b from connecting to the same gate simultaneously. Moreover, when the distance measuring mode is selected, second connection circuit 322 connects signal lines 314a and 314b to gate 221g and 231g. Specifically, second connection circuit 322 connects one of signal line 314a or 314b to one of gate 221g or 231g, and the other of signal line 314a or 314b to the other of gate 221g or 231g. That is, it prevents signal lines 314a and 314b from connecting to the same gate simultaneously.

As illustrated in FIG. 17, second connection circuit 322 includes control signal generation circuit 323 and switching devices 301n, 302n, 303n, 304n, 305n, 306n, 301p, 302p, 303p, 304p, 305p, and 306p.

Each of switching devices 301n to 306n is an n-channel FET including a gate, a source, and a drain. Each of switching devices 301p to 306p is a p-channel FET including a gate, a source, and a drain.

Switching devices 301n and 301p are configured to select one of the low-level side set of signal lines 313a and 314a or the high-level side set of signal lines 313b and 314b, and connect the selected set to control line TG1. Specifically, the connection point of switching devices 301n and 301p (one of the source or drain of each switching device) is connected to control line TG1 (gate 221g). The gates of switching devices 301n and 301p are connected to each other, and a control signal from control signal generation circuit 323 is to be input to the gates thereof. Thus, when one of switching device 301n or 301p is in a conducting state (on), the other is in a non-conducting state (off). Specifically, when switching device 301n is on, the electric potential of one of signal line 313a or 314a is supplied to control line TG1 (gate 221g), and when switching device 301p is on, the electric potential of one of signal line 313b or 314b is supplied to control line TG1 (gate 221g).

Switching devices 302n and 302p are configured to select one of the low-level side set of signal lines 313a and 314a or the high-level side set of signal lines 313b and 314b, and connect the selected set to control line PRS1. Specifically, the connection point of switching devices 302n and 302p (one of the source or drain of each switching device) is connected to control line PRS1 (gate 231g). The gates of switching devices 302n and 302p are connected to each other, and a control signal from control signal generation circuit 323 is to be input to the gates thereof. Thus, when one of switching device 302n or 302p is in a conducting state (on), the other is in a non-conducting state (off). Specifically, when switching device 302n is on, the electric potential of one of signal line 313a or 314a is supplied to control line PRS1 (gate 231g), and when switching device 302p is on, the electric potential of signal line 313b or 314b is supplied to control line PRS1 (gate 231g).

Switching device 303n is provided to switch between conduction and nonconduction between signal line 313a and control line TG1 (gate 221g). Switching device 304n is provided to switch between conduction and nonconduction between signal line 313a and control line PRS1 (gate 231g). The gates of switching devices 303n and 304n are connected to each other, and a control signal from control signal generation circuit 323 is to be input to the gates thereof. Thus, switching devices 303n and 304n are turned on simultaneously and turned off simultaneously. When both switching device 303n and switching device 301n are on, the electric potential of signal line 313a is supplied to control line TG1. When both switching device 304n and switching device 302n are on, the electric potential of signal line 313a is supplied to control line PRS1.

Switching device 303p is provided to switch between conduction and nonconduction between signal line 313b and control line TG1 (gate 221g). Switching device 304p is provided to switch between conduction and nonconduction between signal line 313b and control line PRS1 (gate 231g). The gates of switching devices 303p and 304p are connected to each other, and a control signal from control signal generation circuit 323 is to be input to the gates thereof. Thus, switching devices 303p and 304p are turned on simultaneously and turned off simultaneously. When both switching device 303p and switching device 301p are on, the electric potential of signal line 313b is supplied to control line TG1. When both switching device 304p and switching device 302p are on, the electric potential of signal line 313b is supplied to control line PRS1.

Switching device 305n is provided to switch between conduction and nonconduction between signal line 314a and control line TG1 (gate 221g). Switching device 306n is provided to switch between conduction and nonconduction between signal line 314a and control line PRS1 (gate 231g). The gates of switching devices 305n and 306n are connected to each other, and a control signal from control signal generation circuit 323 is to be input to the gates thereof. Thus, switching devices 305n and 306n are turned on simultaneously and turned off simultaneously. When both switching device 305n and switching device 301n are on, the electric potential of signal line 314a is supplied to control line TG1. When both switching device 306n and switching device 302n are on, the electric potential of signal line 314a is supplied to control line PRS1.

Switching device 305p is provided to switch between conduction and nonconduction between signal line 314b and control line TG1 (gate 221g). Switching device 306p is provided to switch between conduction and nonconduction between signal line 314b and control line PRS1 (gate 231g). The gates of switching devices 305p and 306p are connected to each other, and a control signal from control signal generation circuit 323 is to be input to the gates thereof. Thus, switching devices 305p and 306p are turned on simultaneously and turned off simultaneously. When both switching device 305p and switching device 301p are on, the electric potential of signal line 314b is supplied to control line TG1. When both switching device 306p and switching device 302p are on, the electric potential of signal line 314b is supplied to control line PRS1.

In accordance with the second control signal from operation mode control circuit 132, control signal generation circuit 323 controls on and off of each of switching devices 301n to 306n and switching devices 301p to 304p. Control signal generation circuit 323 is connected to the gates of switching devices 301n to 306n and switching devices 301p to 304p, and outputs a control signal to each gate. The control signal can take one of a high level or a low level.

### <Operation>

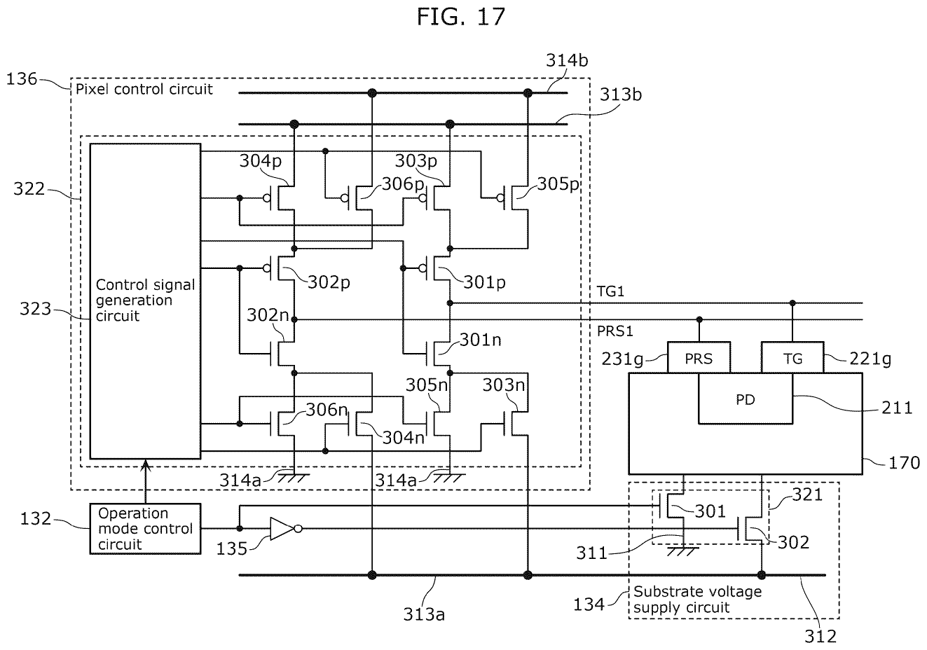

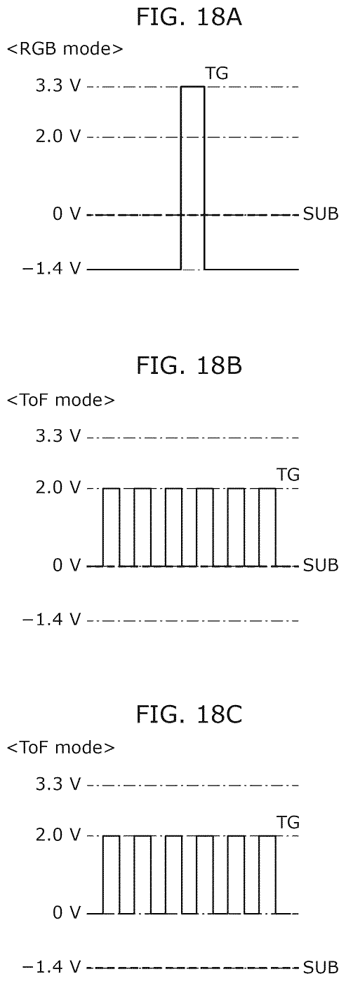

Then, a specific operation of driving circuit 130 is described with reference to FIGS. 18A, 18B, and 18C.

FIG. 18A illustrates an example of an electric potential supplied to gate 221g of first transfer transistor 221 in the RGB mode. FIGS. 18B and 18C each illustrate an example of an electric potential supplied to gate 221g of first transfer transistor 221 in the ToF mode. In each of FIGS. 18A to 18C, TG indicates a temporal change in the voltage level (electric potential) of control line TG1, and SUB indicates a temporal change in the voltage level (electric potential) of substrate 170.

As illustrated in FIG. 18A, in the RGB mode, the low level of control line TG1 is −1.4 V, and the high level thereof is 3.3 V. By contrast, as illustrated in FIGS. 18B and 18C, in the ToF mode, the low level of control line TG1 is 0 V, and the high level thereof is 2.0 V. Thus, the level difference (electric potential difference, amplitude) between the high level and low level of control line TG1 in the ToF mode is less than the level difference (electric potential difference, amplitude) between the high level and low level of control line TG1 in the RGB mode.

In the RGB mode, high-saturation photoelectric converter 211 is needed to obtain a high-definition RGB image. To achieve high-saturation photoelectric converter 211, it is necessary to make the electric potential of photoelectric converter 211 deep (high). Thus, in reading out signal charge, it is necessary to set the electric potential of first transfer transistor 221 much higher. In this case, it is necessary to set the voltage level supplied to gate 221g of first transfer transistor 221 high. In the embodiment, as illustrated in FIG. 18A, the difference between the high level and the low level of control line TG1 (gate 221g) is large. In this way, it is possible to obtain a high-definition RGB image.

Meanwhile, in the ToF mode, to enhance the accuracy of distance measurement, high-speed alternation between the high level and low level of control line TG1 is required. However, when the voltage level of the high level is high, power consumption is increased due to the high-speed alternation.

For this reason, in the embodiment, as illustrated in FIG. 18B, the level difference between the high level and the low level is decreased by suppressing the voltage level of the high level. This can suppress an increase in power consumption. In this way, imaging apparatus 100 and endoscopy system 1 according to the embodiment can achieve both obtainment of a high-definition RGB image and distance measurement with suppressed power consumption.

It should be noted that in the ToF mode, when the level difference of control line TG1 becomes smaller, it may not be possible to sufficiently read out signal charge from photoelectric converter 211 due to the deep electric potential of photoelectric converter 211. By contrast, as illustrated in FIG. 18C, by setting the voltage level of substrate 170 low, it is possible to set the electric potential of photoelectric converter 211 low, which can achieve high-speed readout of signal charge. In this way, imaging apparatus 100 and endoscopy system 1 according to the embodiment can achieve both obtainment of a high-definition RGB image and highly accurate distance measurement with suppressed power consumption.

Hereinafter, operations of driving circuit 130 to achieve the operation modes illustrated in FIGS. 18A to 18C are described with reference to FIG. 17.

For the RGB mode illustrated in FIG. 18A, in substrate voltage supply circuit 134, switching device 301 is maintained in an on-state, and switching device 302 is maintained in an off-state. Thus, the ground electric potential (0 V) is supplied from signal line 311 to substrate 170. In pixel control circuit 136, when the voltage level of control line TG1 is set to a low level, switching devices 301n and 303n are turned on, thereby supplying the electric potential set to signal line 313a (−1.4 V) to control line TG1. When the voltage level of control line TG1 is set to a high level, switching devices 301p and 303p are turned on, thereby supplying the electric potential set to signal line 313b (3.3 V) to control line TG1.

It should be noted that in the RGB mode, second transfer transistor 231 is maintained in an off-state. Specifically, switching devices 302n and 304n are turned on, thereby supplying the electric potential set to signal line 313a (−1.4 V) to control line PRS1.

For the ToF mode illustrated in FIG. 18B, in substrate voltage supply circuit 134, switching device 301 is maintained in an on-state, and switching device 302 is maintained in an off-state. Thus, the ground electric potential (0 V) is supplied from signal line 311 to substrate 170. In pixel control circuit 136, when the voltage level of control line TG1 is set to a low level, switching devices 301n and 305n are turned on, thereby supplying the electric potential set to signal line 314a (0 V) to control line TG1. When the voltage level of control line TG1 is set to a high level, switching devices 301p and 305p are turned on, thereby supplying the electric potential set to signal line 314b (2.0 V) to control line TG1.

It should be noted that in the ToF mode, second transfer transistor 231 alternates between on and off with the phase being inverted from that of first transfer transistor 221. Specifically, when the voltage level of control line PRS1 is set to a low level, switching devices 302n and 306n are turned on, thereby supplying the electric potential set to signal line 314a (0 V) to control line PRS1. When the voltage level of control line PRS1 is set to a high level, switching devices 302p and 306p are turned on, thereby supplying the electric potential set to signal line 314b (2.0 V) to control line PRS1.

For the ToF mode illustrated in FIG. 18C, the operation of substrate voltage supply circuit 134 differs from the operation thereof in the ToF mode illustrated in FIG. 18B. Specifically, in substrate voltage supply circuit 134, switching device 302 is maintained in an on-state, and switching device 301 is maintained in an off-state. Thus, an electric potential (−1.4 V) lower than the ground electric potential is supplied from signal line 312 to substrate 170.

It should be noted that the operations illustrated in FIGS. 18A to 18C are merely examples. Various changes are possible in the RGB mode and the ToF mode.

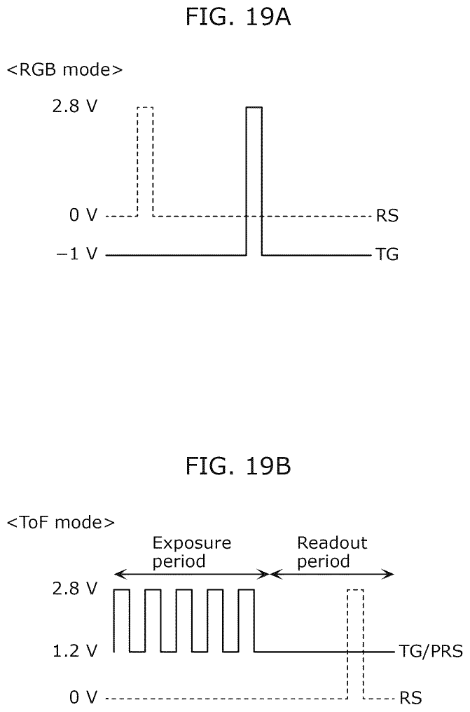

FIG. 19A illustrates examples of electric potentials supplied to the gates of first transfer transistor 221 and reset transistor 121 in the RGB mode. FIG. 19B illustrates examples of electric potentials supplied to the gates of first transfer transistor 221 and second transfer transistor 231 and the gate of reset transistor 121 in the ToF mode. It should be noted that in FIGS. 19A and 19B, TG, PRS, and RS respectively indicate temporal changes in the voltage levels (electric potentials) of control lines TG1, PRS1, and RS.

In the RGB mode, as illustrated also in FIGS. 11 and 12, first transfer transistor 221 is turned on once per frame. Specifically, as illustrated in FIG. 19A, the voltage level of control line TG1 is maintained at a low level (−1 V), and after the voltage level thereof is switched to a high level (2.8 V) at a predetermined timing, the voltage level thereof is maintained at the low level again. In this case, the level difference between the high level and the low level of control line TG1 is 3.8 V. In this way, a high-definition RGB image can be obtained as described above.

By contrast, in the ToF mode, as illustrated also in FIGS. 11 and 12, first transfer transistor 221 and second transfer transistor 231 alternate between on and off at a high speed in a mutually exclusive manner within one frame. Specifically, as illustrated in FIG. 19B, the voltage level of control line TG1 alternates between a low level (1.2 V) and a high level (2.8 V). The same applies to control line PRS1. In this case, the level difference between the high level and the low level of control line TG1 is 2.6 V. In this way, in the ToF mode, it is possible to make the level difference of control line TG1 small, in comparison with the RGB mode, which can suppress an increase in power consumption due to high-speed alternation.

As such, in the instances illustrated in FIGS. 19A and 19B, the value of the high level of control line TG1 is the same. That is, just changing the value of the low level of control line TG1 is effective, and even in this case, it is possible to achieve both obtainment of a high-definition RGB image and distance measurement with suppressed power consumption.

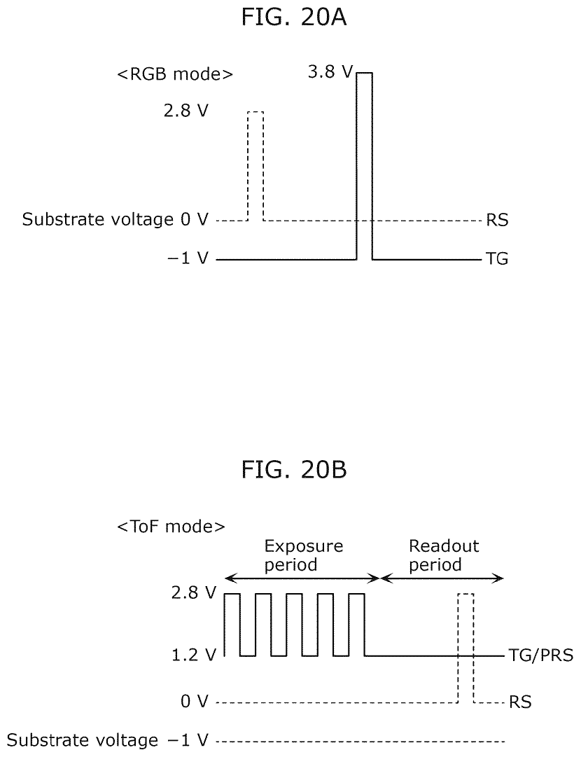

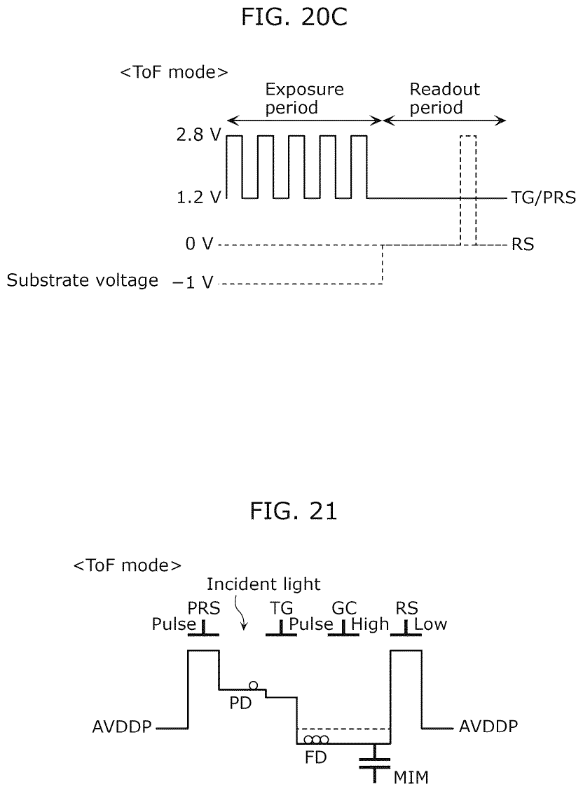

Moreover, as illustrated in FIG. 18C, the voltage level supplied to substrate 170 may be changed. FIG. 20A illustrates examples of electric potentials supplied to the gates of first transfer transistor 221 and reset transistor 121 and substrate 170 in the RGB mode. FIG. 20B illustrates examples of electric potentials supplied to the gates of first transfer transistor 221 and second transfer transistor 231, the gate of reset transistor 121, and substrate 170 in the ToF mode.

As illustrated in FIG. 20A, in the RGB mode, the voltage level supplied to substrate 170 is 0 V. Moreover, in the example illustrated in FIG. 20A, the high level of control line TG1 is 3.8 V. Thus, even higher saturation of photoelectric converter 211 is achieved in the RGB mode. That is, it is possible to read out a high-saturation signal of the photodiode.

By contrast, as illustrated in FIG. 20B, in the ToF mode, the voltage level supplied to substrate 170 is −1 V, which is lower than the voltage level supplied to substrate 170 in RGB mode. This can set the electric potential of photoelectric converter 211 in the ToF mode low, which can increase the speed of signal readout.

It should be noted that in the embodiment, the instance in which driving circuit 130 changes, according to the operation mode, both the voltage supplied to the substrate and the voltage supplied to the gate of the transfer transistor is described as a non-limiting example. Driving circuit 130 need not change one of the voltage supplied to the substrate or the voltage supplied to the gate of the transfer transistor. Specifically, driving circuit 130 may supply a constant voltage to the substrate regardless of the operation mode. Alternatively, driving circuit 130 may set, regardless of the operation mode, the values of the high level and the low level of the voltage supplied to the gate of the transfer transistor to the same values.

Alternatively, as illustrated in FIG. 20C, driving circuit 130 may change the voltage supplied to substrate 170 between the exposure period and the readout period. It should be noted that FIG. 20C illustrates variation examples of the electric potentials supplied to the gates of first transfer transistor 221 and second transfer transistor 231, the gate of reset transistor 121, and substrate 170 in the ToF mode.

Moreover, in the embodiment, the instance in which the two third signal lines and the two fourth signal lines are provided is described. However, one third signal line and one fourth signal line may be provided. In this case, a voltage level (electric potential) set to the one third signal line is switched between the third electric potential and the fourth electric potential. Likewise, a voltage level (electric potential) set to the one fourth signal line is switched between the fifth electric potential and the sixth electric potential.

Moreover, in the embodiment, driving circuit 130 may control the voltage level of power supply line VMIM. FIG. 21 illustrates an electric potential within unit cell 120 when the voltage of capacitor 123 is controlled, in the ToF mode.

Driving circuit 130 supplies voltage level V1 to power supply line VMIM in the RGB mode and voltage level V2 to power supply line VMIM in the ToF mode. Voltage level V2 is higher than voltage level V1. It should be noted that voltage level V1 is, for example, the same as the voltage level supplied to power supply line AVDDP. That is, in the ToF mode, driving circuit 130 causes the electric potential supplied to the second electrode of capacitor 123 to be higher than the electric potential supplied to power supply line AVDDP.

FIG. 21 illustrates in the dashed line the electric potential of charge accumulator FD and capacitor 123 in the RGB mode. As illustrated in FIG. 21, the electric potential of charge accumulator FD and capacitor 123 becomes deeper in the ToF mode, which can facilitate signal readout from photoelectric converter 211. Thus, high-speed readout becomes possible, which can enhance the accuracy of distance measurement.

It should be noted that as a non-limiting example, capacitor 123 is a capacitor having a MIM structure. For instance, the parasitic capacitance caused between the power supply line and a line connected to the source or drain of charge accumulator FD or capacitor connection transistor 122 may be used as capacitor 123. [Positional Relationship between Photoelectric Converter and Gates of Transfer Transistors]

Next, a positional relationship between photoelectric converter 211 and gate 221g of first transfer transistor 221 and a positional relationship between photoelectric converter 211 and gate 231g of second transfer transistor 231 are described. It should be noted that in the following explanations, pixel 201 out of the pixels to be controlled by driving circuit 130 is used as an example. Since the explanations of pixel 201 also apply to pixels 202 to 204, the explanations thereof are omitted.

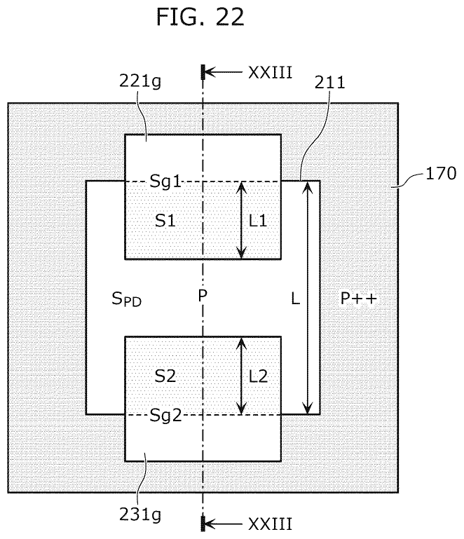

FIG. 22 is a plan view of photoelectric converter 211 according to the embodiment. FIG. 23A is a cross-sectional view taken along line XXIII-XXIII in FIG. 22. As illustrated in FIG. 23A, photoelectric converter 211 includes n-type impurity region 211n and p-type impurity region 211p.

It should be noted that n-type is an example of a first conductivity type. A heavily doped state with a high concentration of n-type impurities is referred to as n⁺ type, and a lightly doped state with a low concertation of n-type impurities is referred to as n⁻ type, and the n⁺ type and the n⁻ type are also examples of the first conductivity type. P-type is an example of a second conductivity type with the reverse polarity of the first conductivity type. A heavily doped state with a high concentration of p-type impurities is referred to as p⁺ type, and a lightly doped state with a low concertation of p-type impurities is referred to as p⁻ type, and the p+ type and the p⁻ type are also examples of the second conductivity type. When substrate 170 is a silicon substrate, a pentad such as phosphorus or arsenic can used as an n-type impurity, and a triad such as boron or aluminum can be used as a p-type impurity.

N-type impurity region 211n is an example of a first semiconductor region and is provided in substrate 170. Impurity region 211n is closer to the back side of substrate 170 (light incident side) than impurity region 211p is.

P-type impurity region 211p is an example of a second semiconductor region and is provided above impurity region 211n inside substrate 170. Impurity region 211p is closer to the front side of substrate 170 (on the side opposite to the light incident side) than impurity region 211n is. The top surface of impurity region 211p corresponds to the top surface of substrate 170.

Each of impurity region 211n and impurity region 211p is formed by doping a predetermined region of substrate 170 with n-type impurities or p-type impurities by, for example, ion implantation. Alternatively, impurity region 211n and impurity region 211p may be formed by performing epitaxial growth while selectively doping the substrate main body with impurities.

In the embodiment, the thickness of photoelectric converter 211 is less than or equal to 3 μm. It should be noted that the thickness of photoelectric converter 211 is equivalent to the depth of photoelectric converter 211 and corresponds to the distance from the top surface of substrate 170, that is, the top surface of p-type impurity region 211p to the bottom surface of n-type impurity region 211n. High-speed readout of signal charge can be achieved by reducing the thickness (depth) of photoelectric converter 211.

If the thickness of photoelectric converter 211 is greater than or equal to 6 μm, a defect tends to occur at an interface with a deep trench isolation (DTI) region for isolating photoelectric converter 211 per pixel, which leads to more dark currents via the defect. By setting the thickness of photoelectric converter 211 to a thickness of 3 μm or less, it is possible to suppress a dark current from occurring, which can enhance the accuracy of distance measurement. In particular, when a visible light band is used as light for distance measurement, the distance can be measured with high accuracy even if the thickness of photoelectric converter 211 is less than or equal to 3 μm. It should be noted that when the defect at the interface can be sufficiently suppressed, the thickness of photoelectric converter 211 may be set to a thickness greater than 3 μm.

In the embodiment, as illustrated in FIG. 22, in a plan view of substrate 170, each of gate 221g of first transfer transistor 221 and gate 231g of second transfer transistor 231 overlaps impurity region 211n. Here, overlapping area S1 of gate 221g and impurity region 211n is at least half of area Sg1 of gate 221g. Overlapping area S2 of gate 231g and impurity region 211n is at least half of area Sg2 of gate 231g. It should be noted that overlapping area S1 of gate 221g and impurity region 211n may be at least 55%, at least 60%, at least 70%, and at least 80% of area Sg1 of gate 221g. Overlapping area S2 of gate 231g and impurity region 211n may be at least 55%, at least 60%, at least 70%, and at least 80% of area Sg2 of gate 231g.

Alternatively, the total of overlapping area S1 of gate 221g and impurity region 211n and overlapping area S2 of gate 231g and impurity region 211n is at least 20% of area S_{PD} of photoelectric converter 211. It should be noted that the total of overlapping area S1 of gate 221g and impurity region 211n and overlapping area S2 of gate 231g and impurity region 211n may be at least 30%, at last 40%, at least 50%, at least 60%, at least 70%, and at least 80% of area S_{PD} of photoelectric converter 211.

Moreover, in a direction in which gate 221g and gate 231g are aligned (in a first direction, a direction parallel to line XXIII-XXIII in FIG. 22), the total of length L1 of the overlapping portion of gate 221g and impurity region 211n and length L2 of the overlapping portion of gate 231g and impurity region 211n is at least 20% of length L of photoelectric converter 211. It should be noted that the total of length L1 and length L2 may be at least 30%, at least 40%, and at least 50% (half) of length L.

As such, in the embodiment, in a plan view of substrate 170, gate 221g of first transfer transistor 221 and gate 231g of second transfer transistor 231 overlap photoelectric converter 211.

Conventionally, in a plan view of substrate 170, gate 221g and gate 231g are disposed to sandwich photoelectric converter 211 without covering photoelectric converter 211. Moreover, to suppress a dark current flowing between gate 221g and gate 231g through the surface of substrate 170, as illustrated in FIG. 23B, p⁺ type impurity region 211pp with a concentration of p-type impurities higher than the concentration of p-type impurities of impurity region 211p or p⁺⁺ type impurity region 211pp with a concentration of p-type impurities sufficiently higher than the concentration of p-type impurities of impurity region 211p is formed. It should be noted that FIG. 23B is a cross-sectional view of a pixel according to a comparison example corresponding to line XXIII-XXIII in FIG. 22.

However, when a pixel is miniaturized, the distance between gate 221g of first transfer transistor 221 and gate 231g of second transfer transistor 231 is decreased, which makes it impossible to form a p⁺⁺ type impurity region with high accuracy. In particular, when a pixel includes two or more gates for distance measurement and global shutter, it is difficult to secure a p⁺⁺ type impurity region. As a result, a dark current increases, which leads to a decrease in the accuracy of distance measurement.

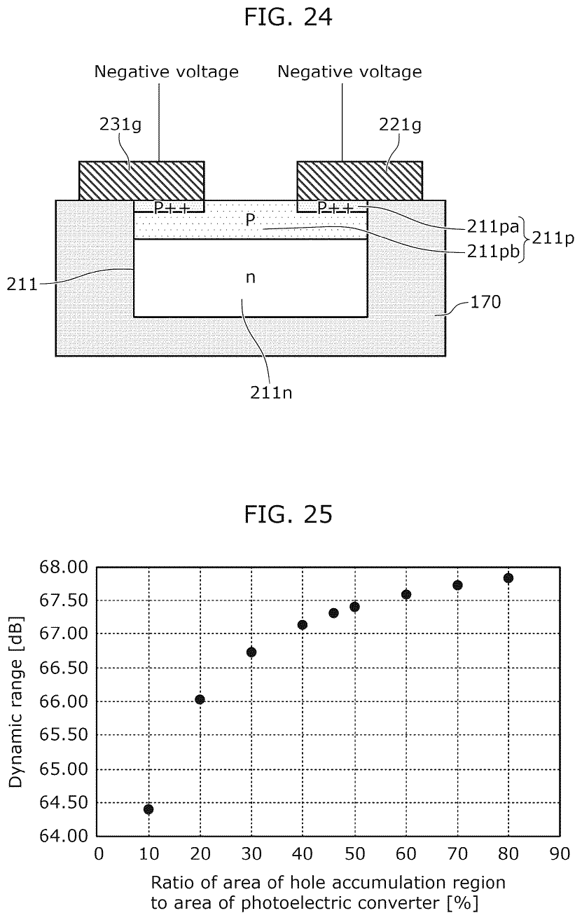

By contrast, in the embodiment, each of gate 221g and gate 231g overlaps p-type impurity region 211p in a plan view of substrate 170. As illustrated in FIG. 24, when driving circuit 130 supplies negative voltages to gate 221g and gate 231g, hole accumulation region 211pa where holes are accumulated is formed in regions directly below gate 221g and gate 231g within impurity region 211p. It should be noted that FIG. 24 is a cross-sectional view illustrating a cross-sectional configuration of photoelectric converter 211 when negative voltages are supplied to the gates of first transfer transistor 221 and second transfer transistor 231.

Hole accumulation region 211pa is an example of a fifth semiconductor region and is a portion of impurity region 211p. The carrier concentration of hole accumulation region 211pa is higher than that of the fourth semiconductor region that is the other portion of impurity region 211p, that is to say, impurity region 211pb. This can suppress a dark current without providing a p⁺⁺ type impurity region.

The dynamic range of imaging apparatus 100 can be expanded by suppressing a dark current. The dynamic range is a parameter indicating the range of the light intensity measurable by imaging apparatus 100. The dynamic range is determined according to the saturation of photoelectric converter 211 and the magnitude of the dark current. The saturation of photoelectric converter 211 is proportional to area S_{PD} of photoelectric converter 211. The magnitude of the dark current is inversely proportional to area S1+area S2 of hole accumulation regions 211pa.

Since area S_{PD} of photoelectric converter 211 is normally determined by the size of unit cell 120, area S_{PD} takes a predetermined fixed value. Thus, it is necessary to increase the area of hole accumulation region 211pa in order to expand the dynamic range.

FIG. 25 illustrates the dynamic range of imaging apparatus 100 with respect to the area ratio of hole accumulation region 211pa. In FIG. 25, the horizontal axis illustrates the ratio of area S1+area S2 of hole accumulation regions 211pa to area S_{PD} of photoelectric converter 211. The vertical axis illustrates the dynamic range of imaging apparatus 100. It should be noted that the area of hole accumulation region 211pa is equivalent to the total of overlapping area S1 of gate 221g and impurity region 211n and overlapping area S2 of gate 231g and impurity region 211n.

As illustrated in FIG. 25, the dynamic range of imaging apparatus 100 increases with an increase in area S1+area S2 of hole accumulation regions 211pa. In particular, when the ratio of area S1+area S2 of hole accumulation regions 211pa to area S_{PD} of photoelectric converter 211 is from 10% to 20%, the expansion width of the dynamic range is large. When the ratio of area S1+area S2 of hole accumulation regions 211pa to area S_{PD} of photoelectric converter 211 becomes 20% or higher, it is possible to make the dynamic range sufficiently large.

It should be noted that if the relationship between the area ratio of hole accumulation region 211pa and the dynamic range is improved with the advancement of the future process technology, the ratio of area S1+area S2 of hole accumulation regions 211pa to area S_{PD} of photoelectric converter 211 need not necessarily be 20% or higher. For instance, the ratio of area S1+area S2 of hole accumulation regions 211pa to area S_{PD} of photoelectric converter 211 may be 10% or higher.

Moreover, the photoelectric converter may include a third semiconductor region provided above the p-type second semiconductor region. The third semiconductor region is, for example, a p⁺ type or p⁺⁺ type impurity region. In this case, the p⁺ type or p⁺⁺ type impurity region serves as a hole accumulation region, which makes it possible to suppress a dark current caused due to an interface defect. In this case, the total of the overlapping area of the control terminal (gate) of the first transfer transistor and the photoelectric converter and the overlapping area of the control terminal (gate) of the second transfer transistor and the photoelectric converter may be at least 10% of the area of the photoelectric converter. Also in this case, dark-current suppression effects similar to those obtained in the above embodiment can be expected.

Moreover, the imaging apparatus may include an electrode disposed, on the photoelectric converter, in a part of the region where neither the control terminal (gate) of the first transfer transistor nor the control terminal (gate) of the second transfer transistor is disposed, and a driving circuit that supplies, to the electrode, a voltage lower than or equal to the electric potential of the substrate. In this case, it is possible to form a hole accumulation layer in a region directly below the electrode. Thus, the hole accumulation layer can perform a function equivalent to the function of a high-concentration p-type impurity layer. This can increase the region of the hole accumulation layer. Thus, the total of the overlapping area of the control terminal (gate) of the first transfer transistor and the photoelectric converter and the overlapping area of the control terminal (gate) of the second transfer transistor and the photoelectric converter may be at least 10% of the area of the photoelectric converter. Also in this case, dark-current suppression effects similar to those obtained in the above embodiment can be expected.

Moreover, the dark current due to the gate insulator film is controlled by the energy band gap. When an insulator film material having a large energy band gap is used, the dark current can be suppressed by the gate insulator film. In this case, the total of the overlapping area of the control terminal (gate) of the first transfer transistor and the photoelectric converter and the overlapping area of the control terminal (gate) of the second transfer transistor and the photoelectric converter may be at least 10% of the area of the photoelectric converter. Also in this case, dark-current suppression effects similar to those obtained in the above embodiment can be expected. It should be noted that the above example is an example in which the dark current is suppressed using the gate insulator film.

A method of fabricating imaging apparatus 100 as described above includes the first step of forming photoelectric converter 211 in substrate 170 and the second step of forming first transfer transistor 221 and second transfer transistor 231 that are connected to photoelectric converter 211.

In the first step, photoelectric converter 211 including impurity region 211p above impurity region 211n is formed. In the first step, for instance, predetermined regions of substrate 170 are each doped with n-type impurities or p-type impurities by ion implantation, thereby forming impurity regions 211n and 211p. Alternatively, impurity region 211n and impurity region 211p may be formed by performing epitaxial growth while selectively doping the substrate main body with impurities.

In the second step, first transfer transistor 221 and second transfer transistor 231 are so formed that each of gate 221g of first transfer transistor 221 and gate 231g of second transfer transistor 231 overlaps impurity region 211p in a plan view of substrate 170. For instance, in the second step, each of gate 221g and gate 231g is disposed above impurity region 211p with an insulator film interposed therebetween in a plan view of substrate 170. Specifically, in the second step, each of gate 221g and gate 231g is formed to overlap impurity region 211p to satisfy the following: in a plan view of substrate 170, overlapping area S1 of gate 221g and impurity region 211p is at least half of area Sg1 of gate 221g and overlapping area S2 of gate 231g and impurity region 211p is at least half of area Sg2 of gate 231g. Alternatively, in the second step, each of gate 221g and gate 231g is formed to overlap impurity region 211p to satisfy the following: in a plan view of substrate 170, the total of overlapping area S1 of gate 221g and impurity region 211p and overlapping area S2 of gate 231g and impurity region 211p is at least 20% of area S_{PD} of photoelectric converter 211. Alternatively, in the second step, each of gate 221g and gate 231g is formed to overlap impurity region 211p to satisfy the following: in a plan view of substrate 170, in the alignment direction of gate 221g and gate 231g, the total of length L1 of the overlapping portion of gate 221g and impurity region 211p and length L2 of the overlapping portion of gate 231g and impurity region 211p is at least 20% of length L of photoelectric converter 211.

For instance, first, an insulator film is formed to cover the surface of substrate 170. The insulator film is formed by, for example, plasma chemical vapor deposition (CVD). After the insulator film is formed, a conducting film is formed. The conducting film is formed by, for example, sputtering or vapor deposition. Gate 221g and gate 231g are formed by patterning the formed conducting film. Patterning is performed by, for example, photolithography and dry etching or wet etching. Here, by performing patterning such that the portion of the conducting film that partially covers photoelectric converter 211 remains, gate 221g and gate 231g are so formed that each gate overlaps photoelectric converter 211 in a plan view of substrate 170.

### OTHER EMBODIMENTS

The imaging apparatus, the distance measuring apparatus, the control method for the imaging apparatus, and the fabrication method of fabricating the imaging apparatus according to one or more aspects, and others are described above on the basis of the embodiment. However, the present disclosure is not limited to the embodiment. The scope of the present disclosure also encompasses embodiments obtained by adding, to the embodiment, various modifications envisioned by those skilled in the art, and embodiments obtained by combining constituent elements in different embodiments, as long as the resultant embodiments do not depart from the scope of the present disclosure.

For instance, in the above embodiment, endoscopy system 1 is indicated as a non-limiting example of the distance measuring apparatus. The distance measuring apparatus may be, for example, a monitoring camera or an object detection apparatus provided to a predetermined building or structure. Alternatively, the distance measuring apparatus may be a sensor apparatus provided to a traveling object such as an autonomous vehicle or a drone. It should be noted that in the above cases, target object 2 may be, for example, a stationary object or a traveling object.

Moreover, for instance, the visible light image need not be an RGB image. The visible light image may be a single-color image such as a black and white image. Moreover, for instance, the first wavelength of light used in the first operation mode may be the same as the second wavelength of blinking light used in the second operation mode. Moreover, an image obtained in the imaging mode may be a still image and may be a moving image.

Moreover, the first operation mode and the second operation mode need not be the imaging mode or the distance measuring mode. For instance, the first operation mode and the second operation mode may be, for example, a short-time exposure mode and a long-time exposure mode in the imaging mode.

Alternatively, the first operation mode and the second operation mode may be, for example, two modes with different frequencies or two modes with different pulse widths in the ToF mode. Alternatively, the first operation mode and the second operation mode may be a pulse ToF mode and a CW-ToF mode.

Moreover, a communication method between the apparatuses described in the above embodiment is not limited to a particular communication method. When wireless communication is performed between the apparatuses, a wireless communication method (communication standard) is, for example, short-range wireless communication such as ZigBee (registered trademark), Bluetooth (registered trademark), or wireless local area network (LAN). Alternatively, the wireless communication method (communication standard) may be communication via a wide area network such as the Internet. Moreover, wired communication may be performed between the apparatuses instead of wireless communication. Specifically, the wired communication is, for example, communication using power line communication (PLC) or a wired LAN.

Moreover, in the above embodiment, processing performed by a particular processing unit may be performed by another processing unit. Moreover, the order in which processes are performed may be changed or processes may be performed in parallel. Moreover, the distribution of the constituent elements of the distance measuring apparatus (distance measuring system) to a plurality of apparatuses is just an example. For instance, a constituent element of an apparatus may be included in another apparatus.

For instance, the processes described in the above embodiment may be achieved by performing centralized processing with the use of a signal apparatus (system) or performing distributed processing with the use of a plurality of apparatuses. Moreover, the processor that executes the above program may be a single processor or two or more processors. That is, centralized processing may be performed, or distributed processing may be performed.

Moreover, in the embodiment, all or a part of the constituent elements such as the controller may be configured as dedicated hardware or may be achieved by executing a software program suitable for each constituent element. Each constituent element may be achieved by a program executer, such as a central processing unit (CPU) or a processor, reading out and executing a software program stored in a recording medium, such as a hard disk drive (HDD) or semiconductor memory.

Moreover, a constituent element such as the controller may be configured as one electronic circuit or a plurality of electronic circuits. The one electronic circuit or each of the plurality of electronic circuits may be a general-purpose circuit or a dedicated circuit.

The one electronic circuit or each of the plurality of electronic circuits may include, for example, a semiconductor device, an IC, or an LSI. The IC or LSI may be integrated into one chip or a plurality of chips. Although the term, IC or LSI is used here, the term may be changed according to the scale of integration. For example, the term, a system LSI, a very large scale integration (VLSI), or an ultra large scale integration (ULSI) may be used according to the scale of integration. Moreover, a FPGA programmed after manufacturing of an LSI can also be used for the same purpose.

Moreover, a general or specific aspect of the present disclosure may be achieved as a system, an apparatus, a method, an integrated circuit, or a computer program. Alternatively, a general or specific aspect of the present disclosure may be achieved as a non-transitory computer-readable recording medium, such as an optical disk, an HDD, or semiconductor memory in which the computer program is stored. Moreover, a general or specific aspect of the present disclosure may be achieved by any combination of the system, apparatus, method, integrated circuit, computer program, and recording medium.

Moreover, in the above embodiments, various changes, replacement, addition, and omission can be performed within the scope of the claims or equivalent range thereof.

### INDUSTRIAL APPLICABILITY

The present disclosure is usable as an imaging apparatus that can be used for highly accurate distance measurement, and is usable in, for example, an endoscopy system and a monitoring camera.

1. An imaging apparatus comprising:
a first semiconductor layer;
a unit cell that is provided in the first semiconductor layer and includes n pixels, where n is a natural number, and a charge accumulator in which charge generated in the n pixels accumulates; and
a driving circuit, wherein
each of the n pixels includes:
a photoelectric converter;
a first transfer transistor that includes a first control terminal, a first input and output terminal connected to the photoelectric converter, and a second input and output terminal connected to the charge accumulator; and
a second transfer transistor that includes a second control terminal, a third input and output terminal connected to the photoelectric converter, and a fourth input and output terminal different from the third input and output terminal, and
the driving circuit supplies a voltage corresponding to an operation mode selected from among a plurality of operation modes to the first semiconductor layer, the first control terminal, or the second control terminal.

2. The imaging apparatus according to claim 1, wherein
the plurality of operation modes include:
a first operation mode in which to expose at least one of the n pixels to light with a first wavelength; and
a second operation mode in which to expose at least one of the n pixels to blinking light with a second wavelength.

3. The imaging apparatus according to claim 1, wherein
the driving circuit includes:
a first voltage supply circuit that supplies a voltage to the first semiconductor layer; and
a second voltage supply circuit that supplies a voltage to at least one of the first control terminal or the second control terminal.

4. The imaging apparatus according to claim 2, wherein
the driving circuit includes a first voltage supply circuit that supplies a voltage to the first semiconductor layer, and
the first voltage supply circuit includes:
a first signal line set to a first electric potential;
a second signal line set to a second electric potential different from the first electric potential; and
a first connection circuit that switches between the first signal line and the second signal line according to the operation mode and connects the first signal line or the second signal line to the first semiconductor layer.

5. The imaging apparatus according to claim 4, wherein
the second electric potential is lower than the first electric potential, and
when the first operation mode is selected, the first connection circuit connects the first signal line to the first semiconductor layer, and when the second operation mode is selected, the first connection circuit connects the second signal line to the first semiconductor layer.

6. The imaging apparatus according to claim 2, wherein
the driving circuit includes a second voltage supply circuit that supplies a voltage to at least one of the first control terminal or the second control terminal, and
the second voltage supply circuit includes:
one or more third signal lines set to at least one of a third electric potential or a fourth electric potential higher than the third electric potential;
one or more fourth signal lines set to at least one of a fifth electric potential or a sixth electric potential higher than the fifth electric potential; and
a second connection circuit that switches between the one or more third signal lines and the one or more fourth signal lines according to the operation mode, and connects the one or more third signal lines or the one or more fourth signal lines to at least one of the first control terminal or the second control terminal.

7. The imaging apparatus according to claim 6, wherein
an electric potential difference between the fourth electric potential and the third electric potential differs from an electric potential difference between the sixth electric potential and the fifth electric potential.

8. The imaging apparatus according to claim 6, wherein
an electric potential difference between the fourth electric potential and the third electric potential is larger than an electric potential difference between the sixth electric potential and the fifth electric potential, and
when the first operation mode is selected, the second connection circuit connects the one or more third signal lines to at least one of the first control terminal or the second control terminal, and when the second operation mode is selected, the second connection circuit connects the one or more fourth signal lines to at least one of the first control terminal or the second control terminal.

9. The imaging apparatus according to claim 2, wherein
the driving circuit includes a second voltage supply circuit that supplies a voltage to at least one of the first control terminal or the second control terminal, and
the second voltage supply circuit includes:
a seventh signal line set to a seventh electric potential;
an eighth signal line set to an eighth electric potential different from the seventh electric potential; and
a third connection circuit that switches between the seventh signal line and the eighth signal line according to the operation mode, and connects the seventh signal line or the eighth signal line to at least one of the first control terminal or the second control terminal.

10. The imaging apparatus according to claim 9, wherein
the eighth electric potential is lower than the seventh electric potential, and
when the first operation mode is selected, the third connection circuit connects the seventh signal line to at least one of the first control terminal or the second control terminal, and when the second operation mode is selected, the third connection circuit connects the eighth signal line to at least one of the first control terminal or the second control terminal.

11. The imaging apparatus according to claim 2, wherein
the unit cell includes:
a capacitor that includes a first electrode and a second electrode; and
a switching device connected in series between the first electrode and the charge accumulator, and
the switching device maintains conduction between the capacitor and the charge accumulator in the second operation mode, and interrupts conduction between the capacitor and the charge accumulator in the first operation mode.

12. The imaging apparatus according to claim 11, wherein
in the second operation mode, the driving circuit causes an electric potential to be supplied to the second electrode to be lower than an electric potential supplied to the fourth input and output terminal.

13. A distance measuring apparatus comprising:
a light source;
the imaging apparatus according to claim 1; and
an arithmetic circuit that calculates a distance to a target object in accordance with a signal output from the imaging apparatus.

14. A control method for the imaging apparatus according to claim 1, the control method comprising:
in an operation mode in which to expose at least one of the n pixels to blinking light with a second wavelength, in a period of exposure to the blinking light with the second wavelength, alternating between conduction and nonconduction to avoid simultaneous conduction of the first transfer transistor and the second transfer transistor; and
in an operation mode in which to expose at least one of the n pixels to light with a first wavelength, in a period of exposure to the light with the first wavelength, maintaining the first transfer transistor and the second transfer transistor in a non-conducting state, and causing only the first transfer transistor to enter a conducting state at a predetermined timing.
